(19) United States
(12) Patent Application Publication
(10) Pub. No.: US 2026/0047295 A1
(43) Pub. Date: Feb. 12, 2026

(54) DISPLAY DEVICE, OPTICAL DEVICE, AND ELECTRONIC DEVICE

(71) Applicant: Samsung Display Co., Ltd., Yongin-si (KR)

(72) Inventor: Chun Gi YOU, Yongin-si (KR)

(21) Appl. No.: 19/204,004

(22) Filed: May 9, 2025

(30) Foreign Application Priority Data
Aug. 12, 2024 (KR) 10-2024-0107270

(51) Int. Cl. H10K 59/131; G02B 27/01; H10K 59/80; H10K 102/20

(52) U.S. Cl. CPC H10K 59/1315; G02B 27/0172; H10K 59/80522; G02B 2027/0178; H10K 2102/20

(57) ABSTRACT

A display device, an optical device including the display device, and an electronic device including the display device are disclosed. The display device, the optical device, and the electronic device may minimize or reduce current reduction (or minimize or reduce a degree or occurrence of current reduction) in a cathode contact area. The display device may include: a substrate; a first electrode on the substrate; a pixel defining layer on the first electrode; a light emitting stack on the first electrode and the pixel defining layer; a second electrode on the light emitting stack; and a cathode pad connected to the second electrode through a contact area defined by the pixel defining layer in a cathode contact area of the substrate, wherein the cathode pad may be continuous in the contact area without disconnection.

### CROSS-REFERENCE TO RELATED APPLICATION

The present application claims priority to and the benefit of Korean Patent Application No. 10-2024-0107270, filed on Aug. 12, 2024, in the Korean Intellectual Property Office, the entire content of which is incorporated herein by reference.

### BACKGROUND

### 1. Field

One or more embodiments of the present disclosure relate to a display device, and, for example, to a display device, an optical device including the display device, and an electronic device including the display device, which are capable of minimizing or reducing current reduction (or minimizing or reducing a degree or occurrence of current reduction) in a cathode contact area.

### 2. Description of the Related Art

A head mounted display (HMD) is an image display device that is worn on a user's head in the form of glasses and/or helmets to focus the image at a close distance in front of the user's eyes. The head mounted display may implement or utilize virtual reality (VR) and/or augmented reality (AR).

The head mounted display magnifies an image displayed on a small display device by using a plurality of lenses and displays the magnified image. Therefore, the display device applied to the head mounted display should provide high-resolution images, for example, images with a resolution of 3000 pixels per inch (PPI) or higher. To this end, an organic light emitting diode on silicon (OLEDoS), which is a high-resolution small organic light emitting display device, is used as the display device applied to the head mounted display. The OLEDoS is an image display device in which an organic light emitting diode (OLED) is arranged or provided on a semiconductor wafer substrate on which a complementary metal oxide semiconductor (CMOS) is arranged or provided.

### SUMMARY

One or more aspects of embodiments of the present disclosure are directed toward a display device, an optical device including the display device, and an electronic device including the display device that are capable of minimizing or reducing current reduction (or minimizing or reducing a degree or occurrence of current reduction) in a cathode contact area.

Additional aspects of embodiments will be set forth in part in the description which follows and, in part, will be apparent from the description or may be learned by practice of the presented embodiments of the disclosure.

According to one or more embodiments of the present disclosure, a display device includes: a substrate; a first electrode on the substrate; a pixel defining layer on the first electrode; a light emitting stack on the first electrode and the pixel defining layer; a second electrode on the light emitting stack; and a cathode pad connected to the second electrode through a contact area defined by the pixel defining layer in a cathode contact area of the substrate, wherein the cathode pad is continuously arranged or provided in the contact area without disconnection (or the cathode pad is continuous in the contact area without disconnection.

According to one or more embodiments of the present disclosure, an optical device includes: a display device; and an optical path changing member on the display device wherein the display device includes: a substrate; a first electrode on the substrate; a pixel defining layer on the first electrode; a light emitting stack on the first electrode and the pixel defining layer; a second electrode on the light emitting stack; and a cathode pad connected to the second electrode through a contact area defined by the pixel defining layer in a cathode contact area of the substrate, wherein the cathode pad is continuously arranged or provided in the contact area without disconnection (or the cathode pad is continuous in the contact area without disconnection).

According to one or more embodiments of the present disclosure, an electronic device includes: a display device including a screen, wherein the display device further includes: a substrate; a first electrode on the substrate; a pixel defining layer on the first electrode; a light emitting stack on the first electrode and the pixel defining layer; a second electrode on the light emitting stack; and a cathode pad connected to the second electrode through a contact area defined by the pixel defining layer in a cathode contact area of the substrate, wherein the cathode pad is continuously arranged or provided in the contact area without disconnection (or the cathode pad is continuous in the contact area without disconnection).

The display device according to one or more embodiments may include a cathode pad that is continuously arranged or provided in the contact area without disconnection (or a cathode pad that is continuous in the contact area without disconnection). Therefore, current reduction (or a degree or occurrence of current reduction) in the cathode contact area may be minimized or reduced. Accordingly, image quality of the display device may be improved or enhanced.

### BRIEF DESCRIPTION OF THE DRAWINGS

The above and other aspects and features of certain embodiments of the present disclosure will become more apparent and more readily appreciated from the following description of one or more embodiments, taken in conjunction with the accompanying drawings, in which:

FIG. 1 is an exploded perspective view illustrating a display device according to one or more embodiments;

FIG. 2 is a block diagram illustrating a display device according to one or more embodiments;

FIG. 3 is an equivalent circuit diagram of a first sub-pixel according to one or more embodiments;

FIG. 4 is a layout diagram illustrating an example of a display panel according to one or more embodiments;

FIGS. 5 and 6 are layout diagrams illustrating examples of the display area of FIG. 4;

FIG. 7 is a cross-sectional view illustrating an example of a display panel taken along the line I1-I1′ of FIG. 5;

FIG. 8 is a cross-sectional view illustrating area A1 of FIG. 7 in more detail;

FIG. 9 is a diagram illustrating an example of a parent substrate to manufacture a display panel according to one or more embodiments;

FIG. 10 is a cross-sectional view of a display panel taken along the line I2-I2′ of FIG. 9;

FIG. 11 is a perspective view of a cathode pad of a display device according to one or more embodiments;

FIG. 12 is a cross-sectional view of a display panel taken along the line I3-I3′ of FIG. 11;

FIG. 13 is a diagram illustrating a connection between the cathode pad and a second electrode of FIG. 12;

FIG. 14 is a cross-sectional view of a second electrode according to one or more embodiments;

FIG. 15 is a perspective view illustrating a head mounted display according to one or more embodiments;

FIG. 16 is an exploded perspective view illustrating an example of the head mounted display of FIG. 15; and FIG. 17 is a perspective view illustrating a head mounted display according to one or more embodiments.

FIG. 18 is a block diagram of an electronic device according to one or more embodiments.

FIGS. 19, 20, and 21 are schematic diagrams of electronic devices according to one or more suitable embodiments.

### DETAILED DESCRIPTION

The subject matter of the present disclosure will be described more fully hereinafter with reference to the accompanying drawings, in which embodiments of the present disclosure are illustrated. The subject matter of the present disclosure may, however, be embodied in one or more forms and should not be construed as being limited to one or more embodiments set forth herein, and one or more changes and modifications may be made. Rather, these embodiments are provided as examples so that this disclosure will be thorough and complete and will fully convey the aspects and features of present disclosure to those skilled in the art to which the present disclosure pertains.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will also be understood that if (e.g., when) a layer is referred to as being “on” another layer or substrate, it may be directly on the other layer or substrate, or intervening layers may also be present therebetween. In contrast, if (e.g., when) a layer is referred to as being “directly on” another layer or substrate, there may be no intervening layers present therebetween.

The same reference numbers indicate substantially the same components throughout the specification.

In the attached drawings, the thickness of layers and regions may be exaggerated to effectively or suitably illustrate the technical contents of the present disclosure.

Although the terms “first”, “second”, and/or the like may be used herein to describe one or more suitable elements, these elements should not be limited by these terms. These terms may be used to distinguish one element from another element.

Thus, a first element discussed herein may be termed a second element without departing from teachings of one or more embodiments. The description of an element as a “first” element may not require or imply the presence of a second element or other elements. The terms “first”, “second”, and/or the like may also be used herein to differentiate different categories or sets of elements. For conciseness, the terms “first”, “second”, and/or the like may represent “first-category (or first-set)”, “second-category (or second-set)”, and/or the like, respectively.

The utilization of “may”, if (e.g., when) describing embodiments of the present disclosure, refers to “one or more embodiments of the present disclosure.” As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within ±30%, ±20%, ±10%, or ±5% of the stated value.

In the context of the present application and unless otherwise defined, the terms “use,” “using,” and “used” may be considered synonymous with the terms “utilize,”“utilizing,”and “utilized,”respectively.

The aspects and features of one or more suitable embodiments of the present disclosure may be combined partially or totally. As will be clearly appreciated by those skilled in the art, technically one or more suitable interactions and operations may be possible. One or more suitable embodiments may be practiced individually or in combination.

Hereinafter, one or more embodiments will be described in more detail with reference to the accompanying drawings.

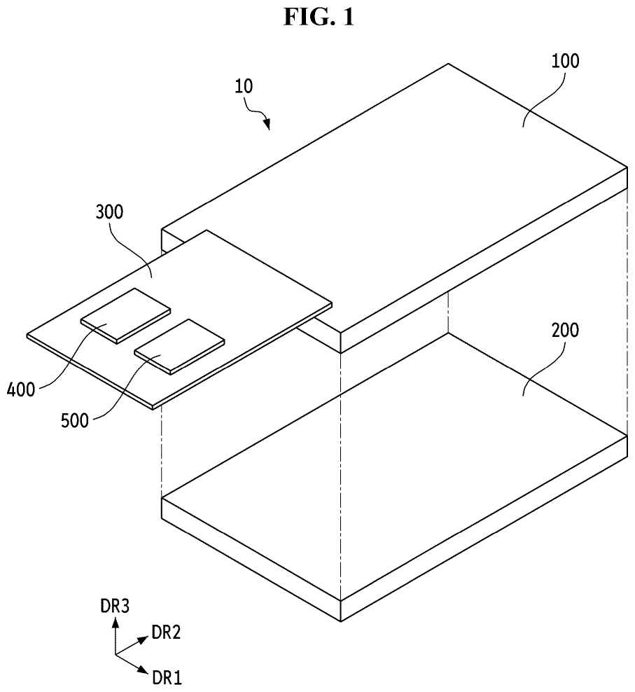

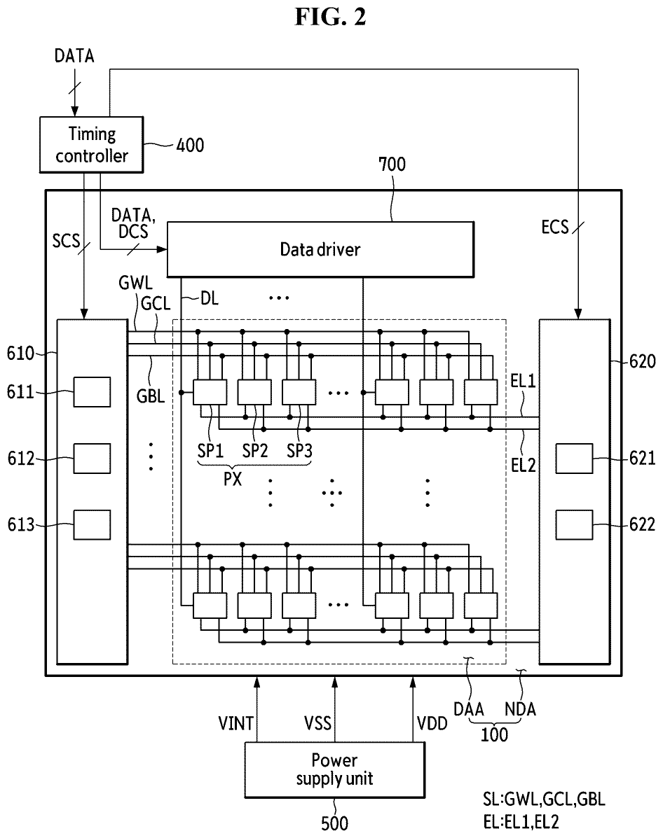

FIG. 1 is an exploded perspective view illustrating a display device according to one or more embodiments. FIG. 2 is a block diagram illustrating a display device according to one or more embodiments.

Referring to FIGS. 1 and 2, a display device 10 according to one or more embodiments may be a device to display a moving image and/or a still image. The display device 10 according to one or more embodiments may be applied to portable electronic devices, such as a mobile phone, a smartphone, a tablet personal computer, a mobile communication terminal, an electronic organizer, an electronic book, a portable multimedia player (PMP), a navigation system, an ultra mobile PC (UMPC) and/or the like. For example, the display device 10 according to one or more embodiments may be applied as a display unit of a television, a laptop, a monitor, a billboard, and/or an Internet-of-Things (IoT) terminal. In one or more embodiments, the display device 10 according to one or more embodiments may be applied to a smart watch, a watch phone, a head mounted display (HMD) to implement or utilize virtual reality and/or augmented reality, and/or the like.

The display device 10 according to one or more embodiments may include a display panel 100, a heat dissipation layer 200, a circuit board 300, a timing control circuit 400, and a power supply circuit 500.

The display panel 100 may have a planar shape (e.g., a substantially planar shape) similar to a quadrilateral shape (e.g., a substantially quadrilateral shape). For example, the display panel 100 may have a planar shape (e.g., a substantially planar shape) similar to a quadrilateral shape (e.g., a substantially quadrilateral shape), having a short side of a first direction DR1 and a long side of a second direction DR2 that crosses (e.g., intersects) the first direction DR1. In the display panel 100, a corner where a short side in the first direction DR1 and a long side in the second direction DR2 meet may be right-angled or rounded having a set or predetermined curvature.

The planar shape (e.g., the substantially planar shape) of the display panel 100 is not limited to a quadrilateral shape (e.g., a substantially quadrilateral shape) and may be a shape similar to another polygonal shape (e.g., another substantially polygonal shape), a circular shape (e.g., a substantially circular shape), or an elliptical shape (e.g., a substantially elliptical shape). The planar shape (e.g., the substantially planar shape) of the display device 10 may conform to the planar shape (e.g., the substantially planar shape) of the display panel 100, but embodiments of the present disclosure are not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA to display an image and a non-display area NDA not to display an image as shown in FIG. 2.

The plurality of pixels PX may be in the display area DAA. The plurality of pixels PX may be in a matrix form in the first direction DR1 and the second direction DR2. The plurality of scan lines SL and the plurality of emission control lines EL may extend in the first direction DR1, while being in the second direction DR2. The plurality of data lines DL may extend in the second direction DR2, while being in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

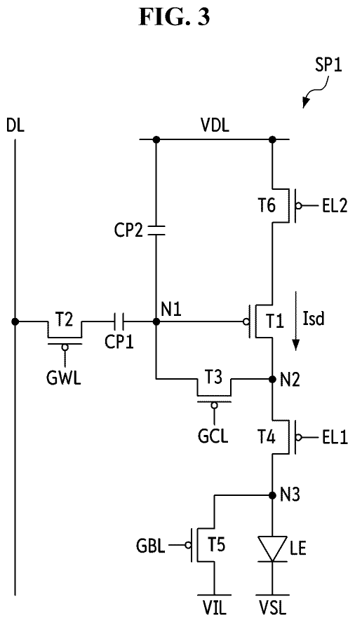

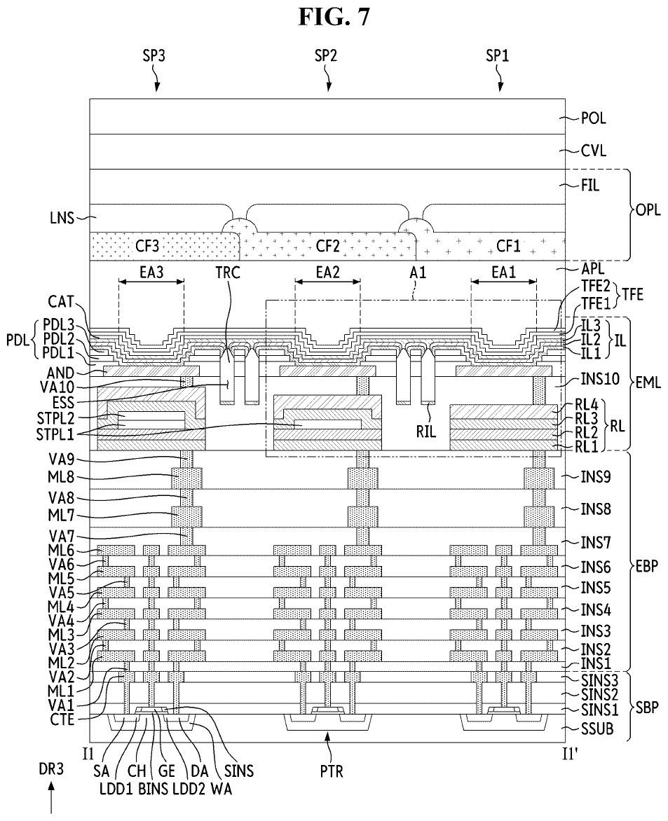

The plurality of pixels PX may include a plurality of sub-pixels SP1, SP2, and SP3. The plurality of sub-pixels SP1, SP2, and SP3 may include a plurality of pixel transistors as shown in FIG. 3, and the plurality of pixel transistors may be formed or provided by a semiconductor process and may be on a semiconductor substrate SSUB (see FIG. 7). For example, the plurality of pixel transistors of the data driver 700 may be of complementary metal oxide semiconductor (CMOS), but embodiments of the present disclosure are not limited thereto.

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may be to receive a data voltage of the data line DL in response to a write scan signal of the write scan line GWL and emit light from the light emitting element according to the data voltage.

The scan driver 610, the emission driver 620, and the data driver 700 may be in the non-display area NDA.

The scan driver 610 may include a plurality of scan transistors, and the emission driver 620 may include a plurality of light emitting transistors. The plurality of scan transistors and the plurality of light emitting transistors may be on the semiconductor substrate SSUB (see FIG. 7) through a semiconductor process. For example, the plurality of scan transistors and the plurality of light emitting transistors may be of CMOS, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may be to receive a scan timing control signal SCS from the timing control circuit 400. The write scan signal output unit 611 may be to generate write scan signals according to the scan timing control signal SCS of the timing control circuit 400 and output them sequentially to the write scan lines GWL. The control scan signal output unit 612 may be to generate control scan signals in response to the scan timing control signal SCS and sequentially output them to the control scan lines GCL. The bias scan signal output unit 613 may be to generate bias scan signals according to the scan timing control signal SCS and output them sequentially to bias scan lines EBL.

The emission driver 620 may include a first emission control driver 621 and a second emission control driver 622. Each of the first emission control driver 621 and the second emission control driver 622 may be to receive an emission timing control signal ECS from the timing control circuit 400. The first emission control driver 621 may be to generate first emission control signals according to the emission timing control signal ECS and sequentially output them to the first emission control lines EL1. The second emission control driver 622 may be to generate second emission control signals according to the emission timing control signal ECS and sequentially output them to the second emission control lines EL2.

The data driver 700 may include a plurality of data transistors, and the plurality of data transistors may be on the semiconductor substrate SSUB (see FIG. 7) through a semiconductor process. For example, the plurality of data transistors may be of CMOS, but embodiments of the present disclosure are not limited thereto.

The data driver 700 may be to receive digital video data DATA and a data timing control signal DCS from the timing control circuit 400. The data driver 700 may be to convert the digital video data DATA into analog data voltages according to the data timing control signal DCS and output the analog data voltages to the data lines DL. In one or more embodiments, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be on one surface of the display panel 100, for example, on the rear surface thereof. The heat dissipation layer 200 may act or serve to dissipate heat generated from the display panel 100. The heat dissipation layer 200 may include a metal layer having relatively high thermal conductivity, such as graphite, silver (Ag), copper (Cu), and/or aluminum (Al).

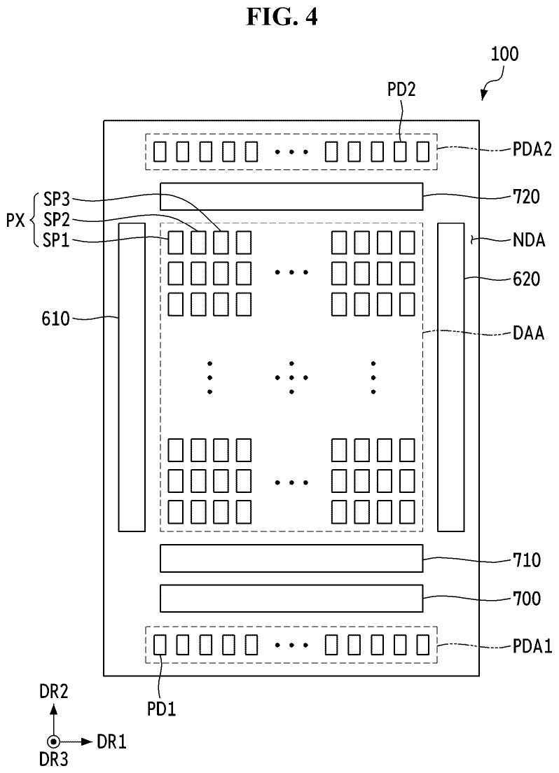

The circuit board 300 may be electrically connected to a plurality of first pads PD1 (see FIG. 4) of a first pad portion PDA1 (see FIG. 4) of the display panel 100 by using a conductive (e.g., electrically conductive) adhesive member, such as an anisotropic conductive (e.g., electrically conductive) layer. The circuit board 300 may be a flexible printed circuit board having a flexible material and/or a flexible layer.

Although the circuit board 300 is illustrated in FIG. 1 as being unfolded, the circuit board 300 may be bent. In one or more embodiments, one end of the circuit board 300 may be on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive (e.g., electrically conductive) adhesive member. One end of the circuit board 300 may be an opposite end of (e.g., facing) the other end of the circuit board 300.

The timing control circuit 400 may be to receive digital video data and timing signals inputted from the outside. The timing control circuit 400 may be to generate the scan timing control signal SCS, the emission timing control signal ECS, and the data timing control signal DCS to control the display panel 100 in response to the timing signals. The timing control circuit 400 may be to output the scan timing control signal SCS to the scan driver 610 and output the emission timing control signal ECS to the emission driver 620. The timing control circuit 400 may be to output the digital video data and the data timing control signal DCS to the data driver 700.

The power supply circuit 500 may be to generate a plurality of panel driving voltages according to a power voltage from the outside. For example, the power supply circuit 500 may be to generate a first driving voltage VSS, a second driving voltage VDD, and a third driving voltage VINT and supply them to the display panel 100. The first driving voltage VSS, the second driving voltage VDD, and the third driving voltage VINT will be described in more detail herein in conjunction with FIG. 3.

Each of the timing control circuit 400 and the power supply circuit 500 may be formed or provided as an integrated circuit (IC) and attached to one surface of the circuit board 300. In one or more embodiments, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In one or more embodiments, each of the timing control circuit 400 and the power supply circuit 500 may be in the non-display area NDA of the display panel 100, similarly to the scan driver 610, the emission driver 620, and the data driver 700. In one or more embodiments, the timing control circuit 400 may include a plurality of timing transistors, and each power supply circuit 500 may include a plurality of power transistors. The plurality of timing transistors and the plurality of power transistors may be on the semiconductor substrate SSUB (see FIG. 7) through a semiconductor process. For example, the plurality of timing transistors and the plurality of power transistors may be of CMOS, but embodiments of the present disclosure are not limited thereto. Each of the timing control circuit 400 and the power supply circuit 500 may be between the data driver 700 and the first pad portion PDA1 (see FIG. 4).

FIG. 3 is an equivalent circuit diagram of a first sub-pixel according to one or more embodiments.

Referring to FIG. 3, the first sub-pixel SP1 may be connected to the write scan line GWL, the control scan line GCL, the bias scan line EBL, the first emission control line EL1, the second emission control line EL2, and the data line DL. Further, the first sub-pixel SP1 may be connected to a first driving voltage line VSL to which the first driving voltage VSS that corresponds to a low potential voltage is applied, a second driving voltage line VDL to which the second driving voltage VDD that corresponds to a high potential voltage is applied, and a third driving voltage line VIL to which the third driving voltage VINT that corresponds to an initialization voltage is applied. For example, the first driving voltage line VSL may be a low potential voltage line, the second driving voltage line VDL may be a high potential voltage line, and the third driving voltage line VIL may be an initialization voltage line. In one or more embodiments, the first driving voltage VSS may be lower than the third driving voltage VINT. The second driving voltage VDD may be higher than the third driving voltage VINT.

The first sub-pixel SP1 may include a plurality of transistors T1 to T6, a light emitting element LE, a first capacitor CP1, and a second capacitor CP2.

The light emitting element LE may be to emit light in response to a driving current that flows through the channel of the first transistor T1. The emission amount of the light emitting element LE may be substantially proportional to the driving current. The light emitting element LE may be between a fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer between the first electrode and the second electrode, but embodiments of the present disclosure are not limited thereto.

For example, the light emitting element LE may be an inorganic light emitting element including a first electrode, a second electrode, and an inorganic semiconductor between the first electrode and the second electrode, in which case the light emitting element LE may be a micro light emitting diode.

The first transistor T1 may be a driving transistor that is to control a source-drain current (hereinafter referred to as “driving current”) that flows between the source electrode and the drain electrode thereof according to a voltage applied to the gate electrode thereof. The first transistor T1 may include a gate electrode connected to a first node N1, a source electrode connected to the drain electrode of a sixth transistor T6, and a drain electrode connected to a second node N2.

A second transistor T2 may be between one electrode of the first capacitor CP1 and the data line DL. The second transistor T2 may be turned on by the write scan signal of the write scan line GWL to connect the one electrode of the first capacitor CP1 to the data line DL. In one or more embodiments, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be between the first node N1 and the second node N2. The third transistor T3 may be turned on by the write control signal of the write control line GCL to connect the first node N1 to the second node N2. For this reason, if (e.g., when) the gate electrode and the source electrode of the first transistor T1 are connected, the first transistor T1 may operate substantially the same as a diode. The third transistor T3 may include a gate electrode connected to the write control line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. In one or more embodiments, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

A fifth transistor T5 may be between the third node N3 and the third driving voltage line VIL. The fifth transistor T5 may be turned on by the bias scan signal of the bias scan line EBL to connect the third node N3 to the third driving voltage line VIL. In one or more embodiments, the third driving voltage VINT of the third driving voltage line VIL may be applied to the first electrode of the light emitting element LE. The fifth transistor T5 may include a gate electrode connected to the bias scan line EBL, a source electrode connected to the third node N3, and a drain electrode connected to the third driving voltage line VIL.

The sixth transistor T6 may be between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. In one or more embodiments, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be between the first node N1 and the drain electrode of the second transistor T2. The first capacitor CP1 may include one electrode connected to the drain electrode of the second transistor T2 and the other electrode connected to the first node N1.

The second capacitor CP2 may be between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 may be a junction between the gate electrode of the first transistor T1, the drain electrode of the third transistor T3, the other electrode of the first capacitor CP1, and the one electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light emitting element LE.

Each of the first transistor T1, the second transistor T2, the third transistor T3, the fourth transistor T4, the fifth transistor T5, and the sixth transistor T6 may be a metal-oxide-semiconductor field effect transistor (MOSFET). For example, each of the first transistor T1, the second transistor T2, the third transistor T3, the fourth transistor T4, the fifth transistor T5, and the sixth transistor T6 may be a positive type (kind) (P-type (kind)) MOSFET, but embodiments of the present disclosure are not limited thereto. Each of the first transistor T1, the second transistor T2, the third transistor T3, the fourth transistor T4, the fifth transistor T5, and the sixth transistor T6 may be a negative type (kind) (N-type (kind)) MOSFET. In one or more embodiments, one or more of the first transistor T1, the second transistor T2, the third transistor T3, the fourth transistor T4, the fifth transistor T5, and the sixth transistor T6 may be P-type (kind) MOSFETs, and each of the remaining transistors may be an N-type (kind) MOSFET.

Although it is illustrated in FIG. 3 that the first sub-pixel SP1 may include the six transistors T1, T2, T3, T4, T5, and T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 as described in conjunction with FIG. 3. Therefore, the description of the equivalent circuit diagram of the second sub-pixel SP2 and the equivalent circuit diagram of the third sub-pixel SP3 may not be repeated in the present disclosure.

FIG. 4 is a layout diagram illustrating an example of a display panel according to one or more embodiments.

Referring to FIG. 4, the display area DAA of the display panel 100 according to one or more embodiments may include the plurality of pixels PX in a matrix form.

The non-display area NDA of the display panel 100 according to one or more embodiments may include the scan driver 610, the emission driver 620, the data driver 700, a first distribution circuit 710, a second distribution circuit 720, the first pad portion PDA1, and a second pad portion PDA2.

The scan driver 610 may be on the first side of the display area DAA, and the emission driver 620 may be on the second side of the display area DAA. For example, the scan driver 610 may be on one side of the display area DAA in the first direction DR1, and the emission driver 620 may be on the other side of the display area DAA in the first direction DR1. For example, the scan driver 610 may be on the left side of the display area DAA, and the emission driver 620 may be on the right side of the display area DAA. However, embodiments of the present disclosure are not limited thereto, and the scan driver 610 and the emission driver 620 may be on both (e.g., simultaneously) the first side and the second side of the display area DAA.

The first pad portion PDA1 may include the plurality of first pads PD1 connected to pads or bumps of the circuit board 300 through a conductive (e.g., electrically conductive) adhesive member. The first pad portion PDA1 may be on the third side of the display area DAA. For example, the first pad portion PDA1 may be on one side of the display area DAA in the second direction DR2. The first pad portion PDA1 may be outside the data driver 700 in the second direction DR2. For example, the first pad portion PDA1 may be closer to the edge of the display panel 100 than the data driver 700.

The second pad portion PDA2 may include a plurality of second pads PD2 that correspond to the inspection pads that may be to test whether the display panel 100 operates normally or suitably. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The second pad portion PDA2 may be on the fourth side of the display area DAA. For example, the second pad portion PDA2 may be on the other side of the display area DAA in the second direction DR2. The second pad portion PDA2 may be outside the second distribution circuit 720 in the second direction DR2. For example, the second pad portion PDA2 may be closer to the edge of the display panel 100 than the second distribution circuit 720.

The first distribution circuit 710 may be to distribute data voltages applied through the first pad portion PDA1 to the plurality of data lines DL. For example, the first distribution circuit 710 may be to distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be on the third side of the display area DAA of the display panel 100. For example, the first distribution circuit 710 may be on one side of the display area DAA in the second direction DR2. For example, the first distribution circuit 710 may be on the lower side of the display area DAA.

The second distribution circuit 720 may be to distribute signals applied through the second pad portion PDA2 to the scan driver 610, the emission driver 620, and the data lines DL. The second pad portion PDA2 and the second distribution circuit 720 may be to inspect the operation of each of the pixels PX in the display area DAA. The second distribution circuit 720 may be on the fourth side of the display area DAA of the display panel 100. For example, the second distribution circuit 720 may be on the other side of the display area DAA in the second direction DR2. For example, the second distribution circuit 720 may be on the upper side of the display area DAA.

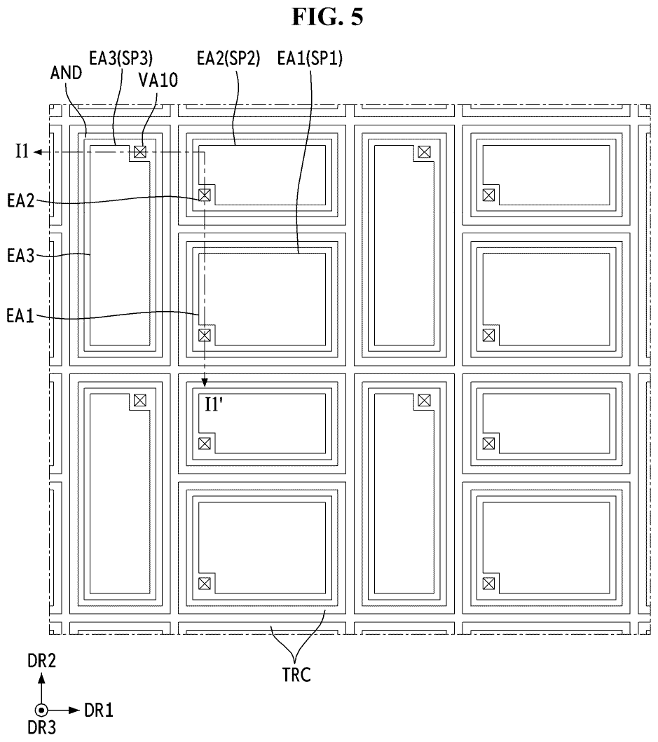

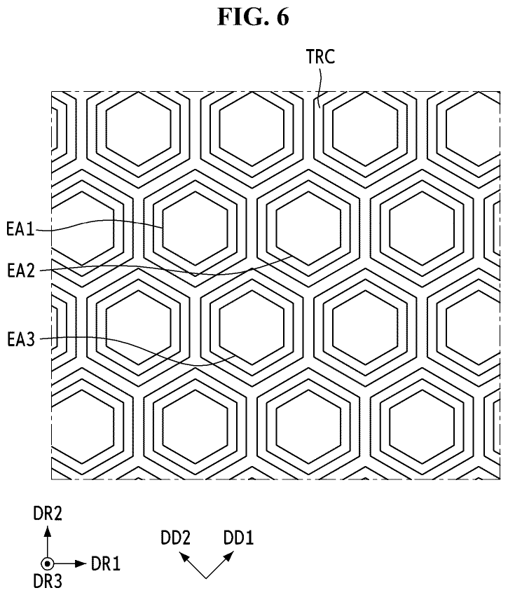

FIGS. 5 and 6 are layout diagrams illustrating examples of the display area of FIG. 4.

Referring to FIGS. 5 and 6, each of the pixels PX may include the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have a polygonal shape (e.g., a substantially polygonal shape), a circular shape (e.g., a substantially circular shape), an elliptical shape (e.g., a substantially elliptical shape), or an atypical shape in plan view.

The maximum length of the first emission area EA1 in the first direction DR1 may be less than the maximum length of the second emission area EA2 in the first direction DR1 and the maximum length of the third emission area EA3 in the first direction DR1. The maximum length of the second emission area EA2 in the first direction DR1 and the maximum length of the third emission area EA3 in the first direction DR1 may be substantially the same.

The maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be less than the maximum length of the third emission area EA3 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have, in plan view, a hexagonal shape of six straight lines as shown in FIGS. 5 and 6, but embodiments of the present disclosure are not limited thereto. The first emission area EA1, the second emission area EA2, and the third emission area EA3 may have a polygonal shape (e.g., a substantially polygonal shape) other than a hexagonal shape (e.g., a substantially hexagonal shape), a circular shape (e.g., a substantially circular shape), an elliptical shape (e.g., a substantially elliptical shape), or an atypical shape in plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In one or more embodiments, the second emission area EA2 and the third emission area EA3 may be adjacent to each other in the second direction DR2. The area of the first emission area EA1, the area of the second emission area EA2, and the area of the third emission area EA3 may be different.

In one or more embodiments, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction normal (e.g., substantially perpendicular) to the first diagonal direction DD1.

The first emission area EA1 may be to emit light of a first color, the second emission area EA2 may be to emit light of a second color, and the third emission area EA3 may be to emit light of a third color. In one or more embodiments, the first color light may be light of a blue wavelength band, the second color light may be light of a green wavelength band, and the third color light may be light of a red wavelength band. For example, the blue wavelength band may be a wavelength band of light whose main or predominant peak wavelength is in the range of about 370 nm to about 460 nm, the green wavelength band may be a wavelength band of light whose main or predominant peak wavelength is in the range of about 480 nm to about 560 nm, and the red wavelength band may be a wavelength band of light whose main or predominant peak wavelength is in the range of about 600 nm to about 750 nm.

In FIGS. 5 and 6, each of the plurality of pixels PX may include three emission areas EA1, EA2, and EA3, but embodiments of the present disclosure are not limited thereto. For example, each of the plurality of pixels PX may include four emission areas.

In one or more embodiments, the layout of the emission areas of the plurality of pixels PX is not limited to those as illustrated in FIGS. 5 and 6. For example, the emission areas of the plurality of pixels PX may be in a stripe structure (e.g., a substantially stripe structure) in which the emission areas are in the first direction DR1, a PENTILE® structure (e.g., an RGBG matrix, RGBG structure, or RGBG matrix structure) in which the emission areas are in a diamond shape (e.g., a substantially diamond shape) or a hexagonal structure (e.g., a substantially hexagonal structure) in which the emission areas having, in plan view, a hexagonal shape (e.g., a substantially hexagonal shape) are arranged or provided as shown in FIG. 6. PENTILE® is a duly registered trademark of Samsung Display Co., Ltd.

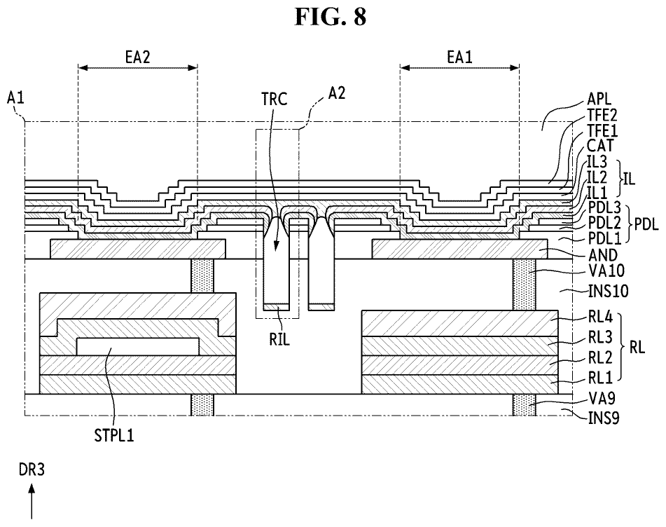

FIG. 7 is a cross-sectional view illustrating an example of a display panel taken along the line I1-I1′ of FIG. 5. FIG. 8 is a cross-sectional view illustrating area A1 of FIG. 7 in more detail.

Referring to FIGS. 7 and 8, the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include the semiconductor substrate SSUB including a plurality of pixel transistors PTR, a plurality of semiconductor insulating layers that cover the plurality of pixel transistors PTR, and a plurality of contact terminals CTE electrically connected to the plurality of pixel transistors PTR, respectively. The plurality of pixel transistors PTR may be the first transistor T1, the second transistor T2, the third transistor T3, the fourth transistor T4, the fifth transistor T5, and the sixth transistor T6 as described with reference to FIG. 4.

The semiconductor substrate SSUB may be a silicon substrate, a germanium substrate, or a silicon-germanium substrate. The semiconductor substrate SSUB may be a substrate doped with a first type (kind) impurity. A plurality of well regions WA may be on the top surface of the semiconductor substrate SSUB. The plurality of well regions WA may be regions doped with a second type (kind) impurity. The second type (kind) impurity may be different from the first type (kind) impurity as described in one or more embodiments. For example, if (e.g., when) the first type (kind) impurity is a p-type (kind) impurity, the second type (kind) impurity may be an n-type (kind) impurity. In one or more embodiments, if (e.g., when) the first type (kind) impurity is an n-type (kind) impurity, the second type (kind) impurity may be a p-type (kind) impurity.

Each of the plurality of well regions WA may include a source region SA that corresponds to the source electrode of the pixel transistor PTR, a drain region DA that corresponds to the drain electrode thereof, and a channel region CH between the source region SA and the drain region DA.

A lower insulating layer BINS may be between a gate electrode GE and the well region WA. A side insulating layer SINS may be on the side surface of the gate electrode GE. The side insulating layer SINS may be on the lower insulating layer BINS.

Each of the source region SA and the drain region DA may be a region doped with the first type (kind) impurity. The gate electrode GE of the pixel transistor PTR may overlap the well region WA in the third direction DR3. The channel region CH may overlap the gate electrode GE in the third direction DR3. The source region SA may be on one side of the gate electrode GE, and the drain region DA may be on the other side of the gate electrode GE.

Each of the plurality of well regions WA may further include a first low-concentration impurity region LDD1 between the channel region CH and the source region SA and a second low-concentration impurity region LDD2 between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that the punch-through phenomenon and/or the hot carrier phenomenon that may be caused by a short channel may be prevented (or a degree to or occurrence of which the punch-through phenomenon and/or the hot carrier phenomenon that may be caused by a short channel may be reduced).

In other words, each well region WA may include two low-concentration impurity regions, LDD1 and LDD2, positioned or provided between the channel region and the source/drain regions. These regions may have lower impurity concentrations than the source and drain regions due to the presence of the lower insulating layer BINS. The inclusion of the two low-concentration impurity regions, LDD1 and LDD2, may increase the distance between the source and drain regions, which in turn may lengthen the channel region. This extended channel may help mitigate the punch-through phenomenon and/or the hot carrier effect, both of which may occur in short-channel transistors. By increasing the channel length, the device's performance and reliability may be improved or enhanced, reducing the likelihood of these adverse effects.

A first semiconductor insulating layer SINS1 may be on the semiconductor substrate SSUB. The first semiconductor insulating layer SINS1 may be of a silicon carbonitride (SiCN)-based inorganic layer and/or a silicon oxide (e.g., SiOₓ, wherein 0<x≤2; e.g., SiO₂)-based inorganic layer, but embodiments of the present disclosure are not limited thereto.

A second semiconductor insulating layer SINS2 may be on the first semiconductor insulating layer SINS1. The second semiconductor insulating layer SINS2 may be of a silicon oxide (e.g., SiOₓ, wherein 0<x≤2; e.g., SiO₂)-based inorganic layer, but embodiments of the present disclosure are not limited thereto.

The plurality of contact terminals CTE may be on the second semiconductor insulating layer SINS2. Each of the plurality of contact terminals CTE may be connected to any one selected from among the gate electrode GE, the source region SA, and the drain region DA of each of the pixel transistors PTR through a hole that penetrates the first semiconductor insulating layer SINS1 and the second semiconductor insulating layer INS2. The plurality of contact terminals CTE may be of any one of copper (Cu), aluminum (Al), tungsten (W), molybdenum (Mo), chromium (Cr), gold (Au), titanium (Ti), nickel (Ni), and neodymium (Nd), or an (e.g., any suitable) alloy thereof.

A third semiconductor insulating layer SINS3 may be on a side surface of each of the plurality of contact terminals CTE. The top surface of each of the plurality of contact terminals CTE may be exposed without being covered by the third semiconductor insulating layer SINS3. The third semiconductor insulating layer SINS3 may be of a silicon oxide (e.g., SiOₓ, wherein 0<x≤2; e.g., SiO₂)-based inorganic layer, but embodiments of the present disclosure are not limited thereto.

The semiconductor substrate SSUB may be replaced with a glass substrate and/or a polymer resin substrate, such as polyimide. In one or more embodiments, thin layer transistors may be on the glass substrate and/or the polymer resin substrate. The glass substrate may be a rigid substrate that does not bend, and the polymer resin substrate may be a flexible substrate that may be bent and/or curved.

The light emitting element backplane EBP may include a plurality of conductive layers ML1 to ML8, a plurality of vias VA1 to VA9, and a plurality of insulating layers INS1 to INS9. In one or more embodiments, the light emitting element backplane EBP may include a plurality of insulating layers INS1 to INS9 between the first conductive layer ML1, the second conductive layer ML2, the third conductive layer ML3, the fourth conductive layer ML4, the fifth conductive layer ML5, the sixth conductive layer ML6, the seventh conductive layer ML7, and the eighth conductive layer ML8.

The first conductive layer ML1, the second conductive layer ML2, the third conductive layer ML3, the fourth conductive layer ML4, the fifth conductive layer ML5, the sixth conductive layer ML6, the seventh conductive layer ML7, and the eighth conductive layer ML8 may act or serve to connect the plurality of contact terminals CTE exposed from the semiconductor backplane SBP to thereby implement or utilize the circuit of the first sub-pixel SP1 as shown in FIG. 3. For example, the first transistor T1, the second transistor T2, the third transistor T3, the fourth transistor T4, the fifth transistor T5, and the sixth transistor T6 may be in the semiconductor backplane SBP, and the connection of the first transistor T1, the second transistor T2, the third transistor T3, the fourth transistor T4, the fifth transistor T5, and the sixth transistor T6 and the first capacitor C1 and the second capacitor C2 may be accomplished or provided through the first conductive layer ML1, the second conductive layer ML2, the third conductive layer ML3, the fourth conductive layer ML4, the fifth conductive layer ML5, the sixth conductive layer ML6, the seventh conductive layer ML7, and the eighth conductive layer ML8. In one or more embodiments, the connection between the drain region that corresponds to the drain electrode of the fourth transistor T4, the source region that corresponds to the source electrode of the fifth transistor T5, and a first electrode AND of the light emitting element LE may also be accomplished or provided through the first conductive layer ML1, the second conductive layer ML2, the third conductive layer ML3, the fourth conductive layer ML4, the fifth conductive layer ML5, the sixth conductive layer ML6, the seventh conductive layer ML7, and the eighth conductive layer ML8.

The first insulating layer INS1 may be on the semiconductor backplane SBP. Each of the first vias VA1 may penetrate the first insulating layer INS1 and be connected to the contact terminal CTE exposed from the semiconductor backplane SBP. Each of the first conductive layers ML1 may be on the first insulating layer INS1 and may be connected to the first via VA1.

The second insulating layer INS2 may be on the first insulating layer INS1 and the first conductive layers ML1. Each of the second vias VA2 may penetrate the second insulating layer INS2 and be connected to the exposed first conductive layer ML1. Each of the second conductive layers ML2 may be on the second insulating layer INS2 and may be connected to the second via VA2.

The third insulating layer INS3 may be on the second insulating layer INS2 and the second conductive layers ML2. Each of the third vias VA3 may penetrate the third insulating layer INS3 and be connected to the exposed second conductive layer ML2. Each of the third conductive layers ML3 may be on the third insulating layer INS3 and may be connected to the third via VA3.

A fourth insulating layer INS4 may be on the third insulating layer INS3 and the third conductive layers ML3. Each of the fourth vias VA4 may penetrate the fourth insulating layer INS4 and be connected to the exposed third conductive layer ML3.

Each of the fourth conductive layers ML4 may be on the fourth insulating layer INS4 and may be connected to the fourth via VA4.

A fifth insulating layer INS5 may be on the fourth insulating layer INS4 and the fourth conductive layers ML4. Each of the fifth vias VA5 may penetrate the fifth insulating layer INS5 and be connected to the exposed fourth conductive layer ML4. Each of the fifth conductive layers ML5 may be on the fifth insulating layer INS5 and may be connected to the fifth via VA5.

A sixth insulating layer INS6 may be on the fifth insulating layer INS5 and the fifth conductive layers ML5. Each of the sixth vias VA6 may penetrate the sixth insulating layer INS6 and be connected to the exposed fifth conductive layer ML5.

Each of the sixth conductive layers ML6 may be on the sixth insulating layer INS6 and may be connected to the sixth via VA6.

A seventh insulating layer INS7 may be on the sixth insulating layer INS6 and the sixth conductive layers ML6. Each of the seventh vias VA7 may penetrate the seventh insulating layer INS7 and be connected to the exposed sixth conductive layer ML6. Each of the seventh conductive layers ML7 may be on the seventh insulating layer INS7 and may be connected to the seventh via VA7.

An eighth insulating layer INS8 may be on the seventh insulating layer INS7 and the seventh conductive layers ML7. Each of the eighth vias VA8 may penetrate the eighth insulating layer INS8 and be connected to the exposed seventh conductive layer ML7. Each of the eighth conductive layers ML8 may be on the eighth insulating layer INS8 and may be connected to the eighth via VA8.

The first conductive layer ML1, the second conductive layer ML2, the third conductive layer ML3, the fourth conductive layer ML4, the fifth conductive layer ML5, the sixth conductive layer ML6, the seventh conductive layer ML7, and the eighth conductive layer ML8 and the first via VA1, the second via VA2, the third via VA3, the fourth via VA4, the fifth via VA5, the sixth via VA6, the seventh via VA7, and the eight via VA8 may be of substantially the same material. The first conductive layer ML1, the second conductive layer ML2, the third conductive layer ML3, the fourth conductive layer ML4, the fifth conductive layer ML5, the sixth conductive layer ML6, the seventh conductive layer ML7, and the eighth conductive layer ML8 and the first via VA1, the second via VA2, the third via VA3, the fourth via VA4, the fifth via VA5, the sixth via VA6, the seventh via VA7, and the eight via VA8 may be of any one of copper (Cu), aluminum (Al), tungsten (W), molybdenum (Mo), chromium (Cr), gold (Au), titanium (Ti), nickel (Ni), and neodymium (Nd), or an (e.g., any suitable) alloy thereof. The first via VA1, the second via VA2, the third via VA3, the fourth via VA4, the fifth via VA5, the sixth via VA6, the seventh via VA7, and the eight via VA8 may be made of substantially the same material. The first insulating layer INS1, the second insulating layer INS2, the third insulating layer INS3, the fourth insulating layer INS4, the fifth insulating layer INS5, the sixth insulating layer INS6, the seventh insulating layer INS7, and the eighth insulating layer INS8 may be of a silicon oxide (e.g., SiOₓ, wherein 0<x≤2; e.g., SiO₂)-based inorganic layer, but embodiments of the present disclosure are not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be about 1360 angstrom (Å). The thickness of each of the second conductive layer ML2, the third conductive layer ML3, the fourth conductive layer ML4, the fifth conductive layer ML5, and the sixth conductive layer ML6 may be about 1440 Å. The thickness of each of the first via VA1, the second via VA2, the third via VA3, the fourth via VA4, the fifth via VA5, and the sixth via VA6 may be about 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be about 9,000 Å. The thickness of each of the seventh via VA7 and the eighth via VA8 may be about 6,000 Å.

A ninth insulating layer INS9 may be on the eighth insulating layer INS8 and the eighth conductive layer ML8. The ninth insulating layer INS9 may be of a silicon oxide (e.g., SiOₓ, wherein 0<x≤2; e.g., SiO₂)-based inorganic layer, but embodiments of the present disclosure are not limited thereto.

Each of the ninth vias VA9 may penetrate the ninth insulating layer INS9 and be connected to the exposed eighth conductive layer ML8. The ninth via VA9 may be of any one of copper (Cu), aluminum (Al), tungsten (W), molybdenum (Mo), chromium (Cr), gold (Au), titanium (Ti), nickel (Ni), and neodymium (Nd), or an (e.g., any suitable) alloy thereof. The thickness of the ninth via VA9 may be about 16,500 Å.

The display element layer EML may be on the light emitting element backplane EBP. The display element layer EML may include light emitting elements LE each including a reflective electrode layer RL, a tenth insulating layer INS10, a tenth via VA10, the first electrode AND, a light emitting stack IL, and a second electrode CAT; a pixel defining layer PDL; and a plurality of trenches TRC.

The reflective electrode layer RL may be on the ninth insulating layer INS9. The reflective electrode layer RL may include at least one reflective electrode RL1, RL2, RL3, and RL4, a first step layer STPL1, and a second step layer STPL2. For example, FIG. 7 illustrates that the one or more reflective electrodes RL1, RL2, RL3, and RL4 may include a first reflective electrode RL1, a second reflective electrode RL2, a third reflective electrode RL3, and a fourth reflective electrode RL4, but embodiments of the present disclosure are not limited thereto.

Each of the first reflective electrodes RL1 may be on the ninth insulating layer INS9 and may be connected to the ninth via VA9. The first reflective electrodes RL1 may be of any one of (e.g., selected from among) copper (Cu), aluminum (Al), tungsten (W), molybdenum (Mo), chromium (Cr), gold (Au), titanium (Ti), nickel (Ni), and/or neodymium (Nd), and/or an (e.g., any suitable) alloy thereof (e.g., of copper (Cu), aluminum (Al), tungsten (W), molybdenum (Mo), chromium (Cr), gold (Au), titanium (Ti), nickel (Ni), and/or neodymium (Nd)). For example, the first reflective electrode RL1 may include titanium nitride (e.g., TiNₓ, wherein 0<x≤2; e.g., TiN).

Each of the second reflective electrodes RL2 may be on the first reflective electrode RL1. The second reflective electrodes RL2 may be of any one of copper (Cu), aluminum (Al), tungsten (W), molybdenum (Mo), chromium (Cr), gold (Au), titanium (Ti), nickel (Ni), and neodymium (Nd), or an (e.g., any suitable) alloy thereof.

For example, the second reflective electrode RL2 may include aluminum (Al).

In the second sub-pixel SP2 and third sub-pixel SP3, the first step layer STPL1 may be on the second reflective electrode RL2. The first step layer STPL1 may not be on the second reflective electrode RL2 in the first sub-pixel SP1.

In the third sub-pixel SP3, the second step layer STPL2 may be on the first step layer STPL1. The second step layer STPL2 may not be on the second reflective electrode RL2 in the first sub-pixel SP1. In one or more embodiments, the second step layer STPL2 may not be on the first step layer STPL1 in the second sub-pixel SP2.

The thickness of the first step layer STPL1 may be set or predetermined in consideration of the wavelength of the light of the first color and a distance from the light emitting stack IL of the second sub-pixel SP2 to the fourth reflective electrode RL4 to advantageously or beneficially reflect the light of the first color emitted from the light emitting stack IL. The thickness of the second step layer STPL2 may be set or predetermined in consideration of the wavelength of the light of the first color and a distance from the light emitting stack IL of the third sub-pixel SP3 to the fourth reflective electrode RL4 to advantageously or beneficially reflect the light of the first color emitted from the light emitting stack IL.

The first step layer STPL1 and the second step layer STPL2 may be of a silicon carbonitride (SiCN)-based inorganic layer and/or a silicon oxide (e.g., SiOₓ, wherein 0<x≤2; e.g., SiO₂)-based inorganic layer, but embodiments of the present disclosure are not limited thereto.

In the first sub-pixel SP1, the third reflective electrode RL3 may be on the second reflective electrode RL2. In the second sub-pixel SP2, the third reflective electrode RL3 may be on the first step layer STPL1. In the third sub-pixel SP3, the third reflective electrode RL3 may be on the second step layer STPL2. The third reflective electrode RL3 may be of any one of copper (Cu), aluminum (Al), tungsten (W), molybdenum (Mo), chromium (Cr), gold (Au), titanium (Ti), nickel (Ni), and neodymium (Nd), or an (e.g., any suitable) alloy thereof. For example, the third reflective electrode RL3 may include titanium nitride (e.g., TiNₓ, wherein 0<x≤2; e.g., TiN).

At least one of the first reflective electrode RL1, the second reflective electrode RL2, or the third reflective electrode RL3 may not be provided.

The fourth reflective electrode RL4 may be on the third reflective electrode RL3. The fourth reflective electrode RL4 may be a layer that is to reflect light from the light emitting stack IL. The fourth reflective electrode RL4 may include metal having relatively high reflectivity to advantageously or beneficially reflect the light. In one or more embodiments, because the fourth reflective electrode RL4 is an electrode that substantially reflects light from the light emitting element LE, the thickness of the fourth reflective electrode RL4 may be greater than the thickness of each of the first reflective electrode RL1, the second reflective electrode RL2, and the third reflective electrode RL3. The fourth reflective electrode RL4 may be of any one of copper (Cu), aluminum (Al), tungsten (W), molybdenum (Mo), chromium (Cr), gold (Au), titanium (Ti), nickel (Ni), and neodymium (Nd), or an (e.g., any suitable) alloy thereof. For example, the fourth reflective electrode RL4 may include aluminum (Al) and/or titanium (Ti).

The tenth insulating layer INS10 may be on the ninth insulating layer INS9 and the fourth reflective electrode RL4. The tenth insulating layer INS10 may be an optical auxiliary layer through which light reflected by the reflective electrode layer RL passes, among light emitted from the light emitting elements LE. The tenth insulating layer INS10 may be of a silicon oxide (e.g., SiOₓ, wherein 0<x≤2; e.g., SiO₂)-based inorganic layer, but embodiments of the present disclosure are not limited thereto.

Each of the tenth vias VA10 may penetrate the tenth insulating layer INS10 and be connected to the exposed ninth metal layer ML9. The tenth via VA10 may be of any one of copper (Cu), aluminum (Al), tungsten (W), molybdenum (Mo), chromium (Cr), gold (Au), titanium (Ti), nickel (Ni), and neodymium (Nd), or an (e.g., any suitable) alloy thereof.

The thickness of the tenth via VA10 may vary in the first sub-pixel SP1, the second sub-pixel SP2, and the third sub-pixel SP3 in order to adjust a resonance distance of light emitted from the light emitting elements LE in at least one of the first sub-pixel SP1, the second sub-pixel SP2, or the third sub-pixel SP3. For example, the thickness of the tenth via VA10 in the third sub-pixel SP3 may be less than the thickness of the tenth via VA10 in each of the first sub-pixel SP1 and the second sub-pixel SP2. Further, the thickness of the tenth via VA10 in the second sub-pixel SP2 may be smaller than the thickness of the tenth via VA10 in the first sub-pixel SP1. For example, the distance between the light emitting stack IL and the reflective electrode layer RL may be different in the first sub-pixel SP1, the second sub-pixel SP2, and the third sub-pixel SP3.

In one or more embodiments, in order to adjust the distance between the light emitting stack IL and the reflective electrode layer RL according to the main or predominant wavelength of light emitted from the first sub-pixel SP1, the presence or absence of the first step layer STPL1 and the second step layer STPL2 and the thickness of each of first step layer STPL1 and the second step layer STPL2 in the first sub-pixel SP1, the second sub-pixel SP2, and the third sub-pixel SP3 may be set or predetermined.

The first electrode AND of each of the light emitting elements LE may be on the tenth insulating layer INS10 and connected to the tenth via VA10. The first electrode AND of each of the light emitting elements LE may be connected to the drain region DA or source region SA of the pixel transistor PTR through the tenth via VA10, the first reflective electrode RL1, the second reflective electrode RL2, the third reflective electrode RL3, and the fourth reflective electrode RL4, the first via VA1, the second via VA2, the third via VA3, the fourth via VA4, the fifth via VA5, the sixth via VA6, the seventh via VA7, the eighth via VA8, and the ninth via VA9, the first conductive layer ML1, the second conductive layer ML2, the third conductive layer ML3, the fourth conductive layer ML4, the fifth conductive layer ML5, the sixth conductive layer ML6, the seventh conductive layer ML7, and the eighth conductive layer ML8, and the contact terminal CTE. The first electrode AND of each of the light emitting elements LE may be of any one of copper (Cu), aluminum (Al), tungsten (W), molybdenum (Mo), chromium (Cr), gold (Au), titanium (Ti), nickel (Ni), and neodymium (Nd), or an (e.g., any suitable) alloy thereof. For example, the first electrode AND of each of the light emitting elements LE may be titanium nitride (e.g., TiNₓ, wherein 0<x≤2; e.g., TiN).

The pixel defining layer PDL may be on a part of the first electrode AND of each of the light emitting elements LE. The pixel defining layer PDL may cover the edge of the first electrode AND of each of the light emitting elements LE. The pixel defining layer PDL may act or serve to partition the first emission areas EA1, the second emission areas EA2, and the third emission areas EA3.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining layer PDL may include a first pixel defining layer PDL1, a second pixel defining layer PDL2, and a third pixel defining layer PDL3. The first pixel defining layer PDL1 may be on the edge of the first electrode AND of each of the light emitting elements LE, the second pixel defining layer PDL2 may be on the first pixel defining layer PDL1, and the third pixel defining layer PDL3 may be on the second pixel defining layer PDL2. The first pixel defining layer PDL1, the second pixel defining layer PDL2, and the third pixel defining layer PDL3 may be of a silicon oxide (e.g., SiOₓ, wherein 0<x≤2; e.g., SiO₂)-based inorganic layer, but embodiments of the present disclosure are not limited thereto. The first pixel defining layer PDL1, the second pixel defining layer PDL2, and the third pixel defining layer PDL3 may each have a thickness of about 500 Å.

If (e.g., when) the first pixel defining layer PDL1, the second pixel defining layer PDL2, and the third pixel defining layer PDL3 are formed or provided as one pixel defining layer, the height of the one pixel defining layer may increase, so that a first encapsulation inorganic layer TFE1 may be cut off due to a step coverage. The step coverage refers to the ratio of the degree of a thin layer coated on an inclined portion to the degree of a thin layer coated on a flat portion (e.g., a substantially flat portion). The lower the step coverage is, the more likely it is that the thin layer will be cut off at inclined portions.

Therefore, in order to reduce the likelihood of the first encapsulation inorganic layer TFE1 being cut off (or to prevent the first encapsulation inorganic layer TFE1 from being cut off) due to the step coverage, the first pixel defining layer PDL1, the second pixel defining layer PDL2, and the third pixel defining layer PDL3 may have a cross-sectional structure having a stepped portion. For example, the width of the first pixel defining layer PDL1 may be greater than the width of the second pixel defining layer PDL2 and the width of the third pixel defining layer PDL3, and the width of the second pixel defining layer PDL2 may be greater than the width of the third pixel defining layer PDL3. The width of the first pixel defining layer PDL1 refers to the horizontal length of the first pixel defining layer PDL1 defined in the first direction DR1 and the second direction DR2.

Each of the plurality of trenches TRC may penetrate the first pixel defining layer PDL1, the second pixel defining layer PDL2, and the third pixel defining layer PDL3. Further, the tenth insulating layer INS10 may be partially recessed at each of the plurality of trenches TRC.

At least one trench TRC may be between the neighboring sub-pixels SP1, SP2, and SP3. Although FIG. 7 illustrates that two trenches TRC are between adjacent sub-pixels SP1, SP2, and SP3, embodiments of the present disclosure are not limited thereto.

The light emitting stack IL may include a plurality of intermediate layers. FIG. 7 illustrates that the light emitting stack IL has a three-tandem structure including the first stack layer IL1, the second stack layer IL2, and the third stack layer IL3, but embodiments of the present disclosure are not limited thereto. For example, the light emitting stack IL may have a two-tandem structure including two stack layers.

In the three-tandem structure, the light emitting stack IL may have a tandem structure including a plurality of stack layers IL1, IL2, and IL3 that are to emit different lights. For example, the light emitting stack IL may include the first stack layer IL1 that is to emit light of the first color, the second stack layer IL2 that is to emit light of the third color, and the third stack layer IL3 that is to emit light of the second color. The first stack layer IL1, the second stack layer IL2, and the third stack layer IL3 may be sequentially stacked.

The first stack layer IL1 may have a structure in which a first hole transport layer, a first organic light emitting layer that is to emit light of the first color, and a first electron transport layer are sequentially stacked. The second stack layer IL2 may have a structure in which a second hole transport layer, a second organic light emitting layer that is to emit light of the third color, and a second electron transport layer are sequentially stacked. The third stack layer IL3 may have a structure in which a third hole transport layer, a third organic light emitting layer that is to emit light of the second color, and a third electron transport layer are sequentially stacked.

A first charge generation layer to supply charges to the second stack layer IL2 and to supply electrons to the first stack layer IL1 may be between the first stack layer IL1 and the second stack layer IL2. The first charge generation layer may include an N-type (kind) charge generation layer that is to supply electrons to the first stack layer IL1 and a P-type (kind) charge generation layer that is to supply holes to the second stack layer IL2. The N-type (kind) charge generation layer may include a dopant of a metal material.

A second charge generation layer to supply charges to the third stack layer IL3 and to supply electrons to the second stack layer IL2 may be between the second stack layer IL2 and the third stack layer IL3. The second charge generation layer may include an N-type (kind) charge generation layer that is to supply electrons to the second stack layer IL2 and a P-type (kind) charge generation layer that is to supply holes to the third stack layer IL3.

The first stack layer IL1 may be on the first electrodes AND and the pixel defining layer PDL. A remaining stack layer RIL made of substantially the same material as the first stack layer IL1 may be on the bottom surface of each of the trenches TRC. Due to the trench TRC, the first stack layer IL1 may be cut off between the neighboring sub-pixels SP1, SP2, and SP3. The second stack layer IL2 may be on the first stack layer IL1. Due to the trench TRC, the second stack layer IL2 may be cut off between the neighboring sub-pixels SP1, SP2, and SP3. A void ESS or an empty space may be between the remaining stack layer RIL and the second stack layer IL2 in each trench TRC. The third stack layer IL3 may be on the second stack layer IL2. The third stack layer IL3 may not be cut off by the trench TRC and may be to cover the second stack layer IL2 in each of the trenches TRC. For example, in the three-tandem structure, each of the plurality of trenches TRC may be a structure to cut off the first stack layer IL1, the second stack layer IL2, the first charge generation layer, and the second charge generation layer of the display element layer EML between the neighboring sub-pixels SP1, SP2, and SP3.

In one or more embodiments, in the two-tandem structure, each of the plurality of trenches TRC may be a structure to cut off the charge generation layer and the lower stack layer between the lower stack layer and the upper stack layer.

In order to stably or suitably cut off the first stack layer IL1 of the display element layer EML between adjacent sub-pixels SP1, SP2, and SP3, the height of each of the plurality of trenches TRC may be greater than the height of the pixel defining layer PDL. The height of each of the plurality of trenches TRC refers to the length of each of the plurality of trenches TRC in the third direction DR3. The height of the pixel defining layer PDL refers to the length of the pixel defining layer PDL in the third direction DR3. In order to cut off the first stack layer IL1, the second stack layer IL2, and the third stack layer IL3 of the display element layer EML between the neighboring sub-pixels SP1, SP2, and SP3, another structure may exist instead of the trench TRC. For example, instead of the trench TRC, a reverse tapered partition wall may be on the pixel defining layer PDL.

In one or more embodiments, FIGS. 7 and 8 illustrate that the first stack layer IL1, the second stack layer IL2, and the third stack layer IL3 may all be in the first emission area EA1, the second emission area EA2, and the third emission area EA3, but embodiments of the present disclosure are not limited thereto. For example, the first stack layer IL1 may be in the first emission area EA1 and may not be provided from the second emission area EA2 and the third emission area EA3. Furthermore, the second stack layer IL2 may be in the second emission area EA2 and may not be provided from the first emission area EA1 and the third emission area EA3. Further, the third stack layer IL3 may be in the third emission area EA3 and may not be provided from the first emission area EA1 and the second emission area EA2. In one or more embodiments, the first color filter CF1, the second color filter CF2, and the third color filter CF3 of the optical layer OPL may not be provided.

The second electrode CAT may be on the third stack layer IL3. The second electrode CAT may be on the third stack layer IL3 in each of the plurality of trenches TRC. The second electrode CAT may be of a transparent (e.g., substantially transparent) conductive (e.g., electrically conductive) material (TCO), such as ITO and/or IZO, that may transmit light or a semi-transmissive conductive (e.g., electrically conductive) material, such as magnesium (Mg), silver (Ag), or an alloy of Mg and Ag.

If (e.g., when) the second electrode CAT is of a semi-transmissive conductive (e.g., electrically conductive) material, the light emission efficiency may be improved or enhanced in each of the first sub-pixel SP1, the second sub-pixel SP2, and the third sub-pixel SP3 due to a micro-cavity effect.

The encapsulation layer TFE may be on the display element layer EML. The encapsulation layer TFE may include at least one inorganic layer TFE1 and TFE2 to prevent oxygen and/or moisture from permeating into the display element layer EML (or to reduce a degree to or occurrence of which oxygen and/or moisture penetrate into the display element layer EML). For example, the encapsulation layer TFE may include a first encapsulation inorganic layer TFE1 and a second encapsulation inorganic layer TFE2.

The first encapsulation inorganic layer TFE1 may be on the second electrode CAT. The first encapsulation inorganic layer TFE1 may be formed or provided as a multilayer in which one or more inorganic layers selected from among silicon nitride (e.g., Si₃N₄ or SiNₓ, wherein 0<x≤2), silicon oxynitride (e.g., Si₂N₂O or SiOₓN_{y}, wherein 0<x≤2 and 0≤y≤2; e.g., SiON), and silicon oxide (e.g., SiOₓ, wherein 0<x≤2; e.g., SiO₂) are alternately stacked. The first encapsulation inorganic layer TFE1 may be formed or provided by a chemical vapor deposition (CVD) process.

The second encapsulation inorganic layer TFE2 may be on the first encapsulation inorganic layer TFE1. The second encapsulation inorganic layer TFE2 may be of titanium oxide (e.g., TiOₓ, wherein 0<x≤2; e.g., TiO₂) and/or aluminum oxide (e.g., AlOₓ, wherein 0<x≤2; Al₂O₃), but embodiments of the present disclosure are not limited thereto. The second encapsulation inorganic layer TFE2 may be formed or provided by an atomic layer deposition (ALD) process. The thickness of the second encapsulation inorganic layer TFE2 may be smaller than the thickness of the first encapsulation inorganic layer TFE1.

The organic layer APL may be a layer to increase or enhance the interfacial adhesion between the encapsulation layer TFE and the optical layer OPL. The organic layer APL may be an organic layer, such as an acrylic resin, an epoxy resin, a phenolic resin, a polyamide resin, and/or a polyimide resin.

The optical layer OPL may include a plurality of color filters CF1, CF2, and CF3, a plurality of lenses LNS, and a filling layer FIL. The plurality of color filters CF1, CF2, and CF3 may include the first color filter CF1, the second color filter CF2, and the third color filter CF3. The first color filter CF1, the second color filter CF2, and the third color filter CF3 may be on the organic layer APL.

The first color filter CF1 may overlap the first emission area EA1 of the first sub-pixel SP1. The first color filter CF1 may be to transmit light of the first color, for example, light of a red wavelength band. Thus, the first color filter CF1 may be to transmit light of the first color among light emitted from the first emission area EA1.

The second color filter CF2 may overlap the second emission area EA2 of the second sub-pixel SP2. The second color filter CF2 may be to transmit light of the second color, for example, light of a green wavelength band. Thus, the second color filter CF2 may be to transmit light of the second color among light emitted from the second emission area EA2.

The third color filter CF3 may overlap the third emission area EA3 of the third sub-pixel SP3. The third color filter CF3 may be to transmit light of the third color, for example, light of a blue wavelength band. Thus, the third color filter CF3 may be to transmit light of the third color among light emitted from the third emission area EA3.

The plurality of lenses LNS may be on the first color filter CF1, the second color filter CF2, and the third color filter CF3, respectively. Each of the plurality of lenses LNS may be a structure to increase the proportion of light directed to the front of the display device 10. Although each of the lenses LNS is illustrated as having a cross-sectional shape that is convex upward, embodiments of the present disclosure are not limited thereto.

The filling layer FIL may be on the plurality of lenses LNS. The filling layer FIL may have a set or predetermined refractive index such that light travels in the third direction DR3 at an interface between the filling layer FIL and the plurality of lenses LNS. Further, the filling layer FIL may be a planarization layer. The filling layer FIL may be an organic layer, such as an acrylic resin, an epoxy resin, a phenolic resin, a polyamide resin, and/or a polyimide resin.

The cover layer CVL may be on the filling layer FIL. The cover layer CVL may be a glass substrate and/or a polymer resin. If (e.g., when) the cover layer CVL is a glass substrate, it may be attached onto the filling layer FIL. In one or more embodiments, the filling layer FIL may act or serve to bond the cover layer CVL. If (e.g., when) the cover layer CVL is a glass substrate, it may act or serve as an encapsulation substrate. If (e.g., when) the cover layer CVL is a polymer resin, it may be directly applied onto the filling layer FIL.

The polarizing plate POL may be on one surface of the cover layer CVL.

The polarizing plate POL may be a structure to prevent visibility degradation (or to reduce a degree or occurrence of visibility degradation) caused by reflection of external light. The polarizing plate POL may include a linear polarizing plate and a phase retardation layer. For example, the phase retardation layer may be a λ/4 plate (or quarter-wave plate), but embodiments of the present disclosure are not limited thereto. However, if (e.g., when) visibility degradation caused by reflection of external light is sufficiently or suitably overcome by the first color filter CF1, the second color filter CF2, and the third color filter CF3, the polarizing plate POL may not be provided.

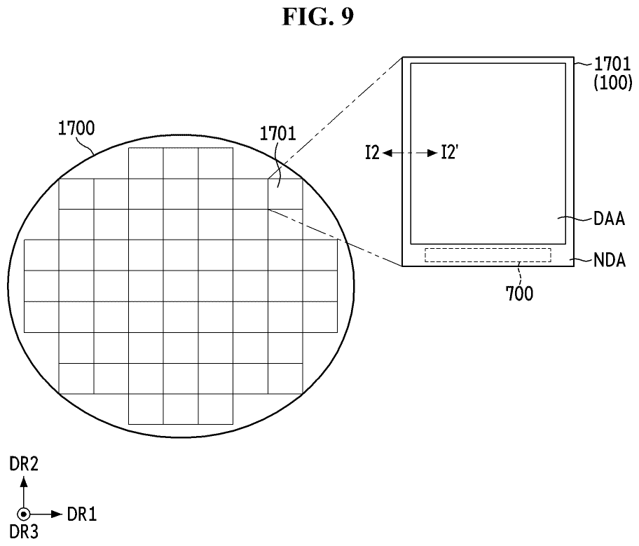

FIG. 9 is a diagram illustrating an example of a mother substrate to manufacture the display panel 100 according to one or more embodiments.

Referring to FIG. 9, a mother substrate 1700 may be a semiconductor wafer to manufacture the OLEDoS display panel 100. In the present disclosure, a semiconductor wafer may be referred to as “semiconductor substrate,” “substrate,” or “semiconductor wafer substrate.”

The mother substrate 1700 may include a plurality of net dies 1701, and one net die 1701 may correspond to one display panel 100. For example, the mother substrate 1700, which is a semiconductor wafer, may include about 76 dies 1701, which refers to that about 76 display panels 100 may be manufactured from one mother substrate 1700.

The plurality of display panels 100 manufactured based on the mother substrate 1700 may be individually separated by a sawing process and/or a grinding process in which the corners of each display panel 100 are polished into a round shape.

The display panel 100 may include the display area DAA where the light emitting element LE is arranged or provided and the non-display area NDA outside the display area DAA.

A driving circuit, such as the data driver 700, may be in the non-display area NDA of the display panel 100. The data driver 700 may be adjacent to one end of the display panel 100 as described in connection with FIG. 4. In the illustrated example, although the data driver 700 is adjacent to the lower end of the display panel 100, embodiments of the present disclosure are not limited thereto.

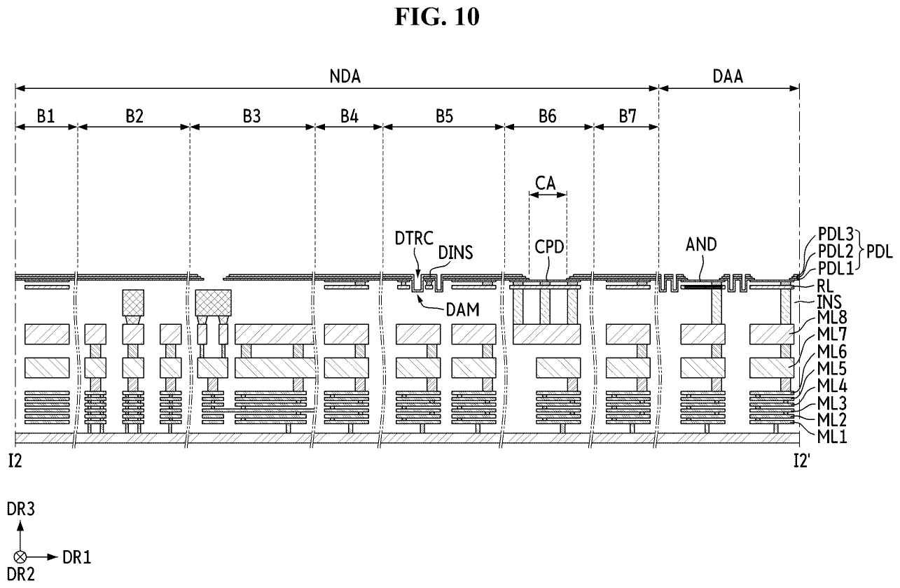

FIG. 10 is a cross-sectional view of a display panel 100 taken along the line I2-I2′ of FIG. 9. In FIG. 10, the pixel defining layer PDL is illustrated on the uppermost layer, and the stacked structures (e.g., the encapsulation layer TFE) on the top of the pixel defining layer PDL may not be provided.

Referring to FIG. 10, the display panel 100 may include a display area DAA in which a light emitting element LE is arranged or provided and a non-display area NDA at the outer edge of the display area DAA.

The non-display area NDA may include a dummy area B1, a moisture permeation/crack prevention area B2, an array test pad area B3, a first dummy circuit area B4, a dam area B5, a cathode contact area B6, and a second dummy circuit area B7.

The dummy area B1 may substantially be an area where one display panel 100 is cut in a sawing process.

In the moisture permeation/crack prevention area B2, patterns (e.g., metal patterns) to prevent air and/or moisture from flowing into the display panel 100 (or to reduce a degree to or occurrence of which air and/or moisture flow into the display panel 100) during the cutting process and/or the grinding process of the display panel 100 may be arranged or provided.

In the array test pad area B3, the inspection pads to inspect whether the display panel 100 operates normally or suitably may be arranged or provided. The inspection pads may be connected to a jig or a probe pin or be connected to an inspection circuit board in an inspection process. For example, a second pad portion PDA2 as described in one or more embodiments may be arranged or provided in the array test pad area B3.

The first dummy circuits may be in the first dummy circuit area B4.

In the dam area B5, at least one dam structure DAM including a dam separator DTRC that penetrates the insulating layer INS may be arranged or provided. Such dam area B5 may be a boundary area where the encapsulation layer TFE that covers the display area DAA extends.

In the cathode contact area B6, a cathode pad CPD to which the second electrode CAT extended from the display area DAA is connected may be arranged or provided. For example, the second electrode CAT may be connected to a first driving voltage line (e.g., VSL of FIG. 3) through the cathode pad CPD in the cathode contact area B6.

A second dummy circuit may be in the second dummy circuit area B7.

The stacked structure of each of the dummy area B1, the moisture permeation/crack prevention area B2, the array test pad area B3, the first dummy circuit area B4, the dam area B5, the cathode contact area B6, and the second dummy circuit area B7 may be similar to the stacked structure of the semiconductor backplane SBP and the light emitting element backplane EBP in the display area DAA. For example, the dummy layers in substantially the same layer as the first conductive layer ML1, the second conductive layer ML2, the third conductive layer ML3, the fourth conductive layer ML4, the fifth conductive layer ML5, the sixth conductive layer ML6, the seventh conductive layer ML7, and the eighth conductive layer ML8 (FIG. 7) of the semiconductor backplane SBP and the light emitting element backplane EBP in the display area DAA may be in each of the dummy area B1, the moisture permeation/crack prevention area B2, the array test pad area B3, the first dummy circuit area B4, the dam area B5, the cathode contact area B6, and the second dummy circuit area B7. Reference numerals ML1 to ML8 as shown in FIG. 10 may denote the dummy conductive layers ML1 to ML8 in substantially the same layer as the first conductive layer ML1, the second conductive layer ML2, the third conductive layer ML3, the fourth conductive layer ML4, the fifth conductive layer ML5, the sixth conductive layer ML6, the seventh conductive layer ML7, and the eighth conductive layer ML8 as shown in FIG. 7.

Among the dummy area B1, the moisture permeation/crack prevention area B2, the array test pad area B3, the first dummy circuit area B4, the dam area B5, the cathode contact area B6, and the second dummy circuit area B7, at least one or more area may further include a dummy reflective electrode on substantially the same layer as the reflective electrode RL in the display area DAA. For example, as illustrated in FIG. 10, each of the dummy area B1, the moisture permeation/crack prevention area B2, the array test pad area B3, the first dummy circuit area B4, the dam area B5, the cathode contact area B6, and the second dummy circuit area B7 may further include a dummy reflective electrode on substantially the same layer as the reflective electrode RL (see FIG. 7) in the display area DAA. Reference numeral RL as shown in FIG. 10 may denote the dummy reflective electrode RL on substantially the same layer as the dummy reflective electrode RL as illustrated in FIG. 7.

Among the dummy area B1, the moisture permeation/crack prevention area B2, the array test pad area B3, the first dummy circuit area B4, the dam area B5, the cathode contact area B6, and the second dummy circuit area B7, at least one or more area may include a dummy conductive (e.g., electrically conductive) layer on substantially the same layer as the first electrode AND (see FIG. 7) in the display area DAA. Reference numeral AND as illustrated in FIG. 10 may denote the dummy conductive layer AND arranged or provided as substantially the same layer as the first electrode AND as illustrated in FIG. 7.

A pixel defining layer PDL extended from the display area DAA may be on the dummy area B1, the moisture permeation/crack prevention area B2, the array test pad area B3, the first dummy circuit area B4, the dam area B5, the cathode contact area B6, and the second dummy circuit area B7. Such pixel defining layer PDL may act or serve as a dam insulating layer DINS that forms the dam structure DAM in the dam area B5.

The dam structure DAM may include a dam separator DTRC that penetrates an insulating layer INS (e.g., the tenth insulating layer INS10 and/or the eleventh insulating layer INS11 of FIG. 7) on a semiconductor substrate (e.g., the semiconductor substrate SSUB of FIG. 7) of the display panel 100, a dam insulating layer DINS on the insulating layer INS at the periphery of the dam separator DTRC, and an encapsulation layer TFE (e.g., the encapsulation layer TFE of FIG. 7) that covers the dam separator DTRC and the dam insulating layer DINS.

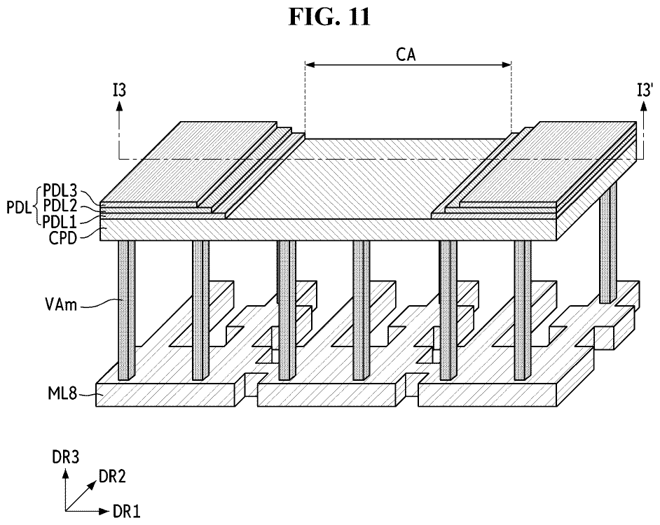

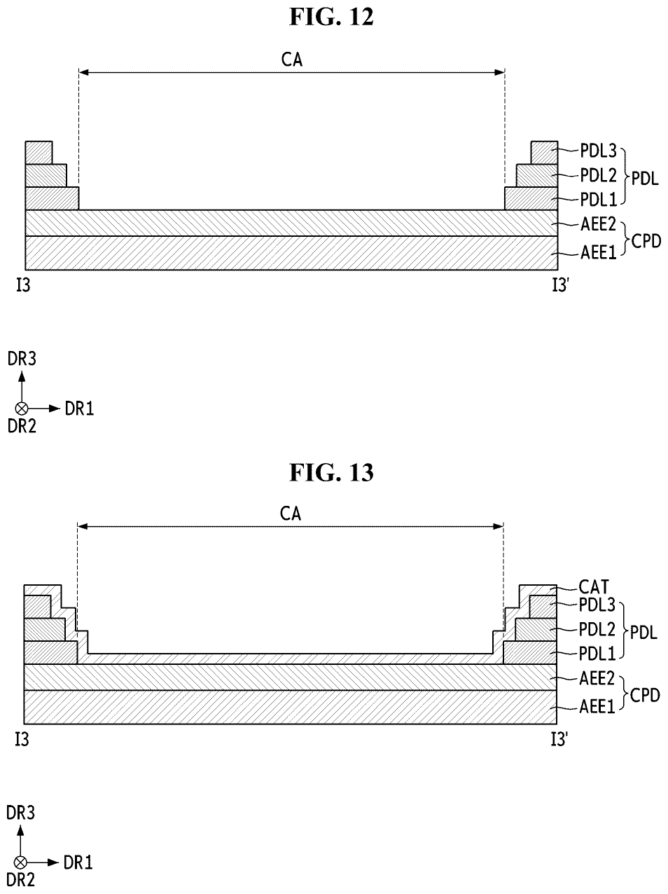

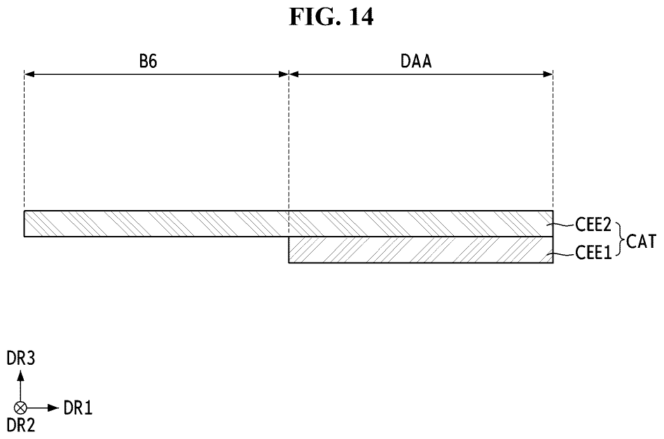

FIG. 11 is a perspective view of a cathode pad CPD of a display device according to one or more embodiments, FIG. 12 is a cross-sectional view of a display panel 100 taken along the line I3-I3′ of FIG. 11, and FIG. 13 is a diagram illustrating a connection between the cathode pad CPD and a second electrode of FIG. 12. In one or more embodiments, the cathode pad CPD of each of FIGS. 11 to 13 may be the cathode pad CPD in the cathode contact area B6 of FIG. 10 as described in one or more embodiments.

As illustrated in FIG. 11, the cathode pad CPD may be exposed to the outside through a contact area CA defined by the pixel defining layer PDL. The edge of the cathode pad CPD may be covered by the pixel defining layer PDL. For example, the pixel defining layer PDL may be at the edge of the cathode pad CPD. The contact area CA may be an open area that penetrates the pixel defining layer PDL.

The pixel defining layer PDL may include a first pixel defining layer PDL1, a second pixel defining layer PDL2, and a third pixel defining layer PDL3 stacked sequentially along the third direction DR3 on the cathode pad CPD. The first pixel defining layer PDL1 may be in contact with the edge of the cathode pad CPD. The second pixel defining layer PDL2 may be between the first pixel defining layer PDL1 and the third pixel defining layer PDL3.

According to one or more embodiments, as illustrated in FIGS. 11 and 12, the cathode pad CPD of the contact area CA may have substantially the same area as the contact area CA. For example, in plan view, the area of the cathode pad CPD and the area of the contact area CA may be substantially the same. For example, in plan view, the cathode pad CPD may entirely occupy the contact area CA in the contact area CA. This is because the cathode pad CPD is in a substantially continuous shape that is without disconnection in the contact area CA. As described in one or more embodiments, because the cathode pad CPD has a flat shape (e.g., a substantially flat shape) without disconnections or steps in the contact area CA, a contact surface between the cathode pad CPD and the second electrode CAT in the contact area CA may increase. In one or more embodiments, the resistance at the contact portion between the cathode pad CPD and the second electrode CAT may be reduced, and the current reduction at the contact portion may be minimized or reduced.

In other words, the cathode pad CPD in the contact area CA may have substantially the same area as the contact area CA. For example, in plan view, the area of the cathode pad CPD and the area of the contact area CA may be substantially the same. The cathode pad CPD may entirely occupy the contact area CA because it is arranged or provided in a substantially continuous shape without disconnection in the contact area CA.

The cathode pad CPD may be composed of a conductive (e.g., electrically conductive) material, such as aluminum or an aluminum alloy, which ensures efficient or suitable electrical conductivity. The pixel defining layer PDL, which includes the first pixel defining layer PDL1, the second pixel defining layer PDL2, and the third pixel defining layer PDL3, may be sequentially stacked along the third direction DR3 on the cathode pad CPD. The first pixel defining layer PDL1 may be in direct contact with the edge of the cathode pad CPD, while the second pixel defining layer PDL2 is between the first pixel defining and the third pixel defining layer.

Because the cathode pad CPD has a flat shape (e.g., a substantially flat shape) without disconnections or steps in the contact area CA, the contact surface between the cathode pad CPD and the second electrode CAT in the contact area CA may be maximized or increased. This increased contact surface area may enhance the electrical connection, thereby reducing the resistance (or reducing a degree or occurrence of the resistance) at the contact portion between the cathode pad CPD and the second electrode CAT. Consequently, the current reduction at the contact portion may be minimized or reduced, ensuring or providing efficient or suitable current flow and enhancing the performance of the display panel.

The cathode pad CPD may be connected to the first driving voltage line VSL through a via and an eighth conductive layer ML8 in the cathode contact area B6. A via VAm of the cathode contact area B6 may be connected to the eighth conductive layer ML8 of the cathode contact area B6. The eighth conductive layer ML8 of the cathode contact area B6 may be connected to the first driving voltage line VSL through other conductive (e.g., electrically conductive or conductor) layers.

As illustrated in FIG. 12, the cathode pad CPD may include a plurality of conductive layers AEE1 and AEE2. For example, the cathode pad CPD may include a first conductive layer AEE1 and a second conductive layer AEE2. The first conductive layer AEE1 may be on the via VAm, and the second conductive layer AEE2 may be on the first conductive layer AEE1. The first conductive layer AEE1 may be connected to the via VAm, and the second conductive layer AEE2 may be connected to the first conductive layer AEE1 and the cathode electrode CAT. The first conductive layer AEE1 and the second conductive layers AEE2 may be in contact (or direct contact) with each other.

The first conductive layer AEE1 of the cathode pad CPD may include, for example, aluminum (Al).

The second conductive layer AEE2 of the cathode pad CPD may include, for example, titanium nitride (e.g., TiNₓ, wherein 0<x≤2; e.g., TiN).

As illustrated in FIG. 13, the second electrode CAT may be connected to the cathode pad CPD in the cathode contact area B6. For example, in the cathode contact area B6, the second electrode CAT may be connected to the second conductive layer AEE2 of the cathode pad CPD exposed through a contact area CA of the pixel defining layer PDL.

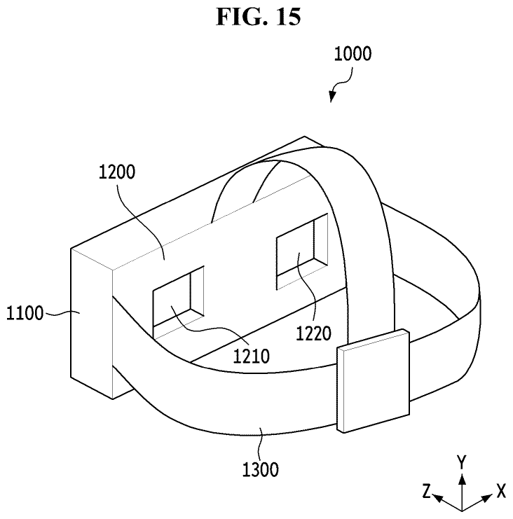

FIG. 14 is a cross-sectional view of a second electrode CAT according to one or more embodiments.

As illustrated in FIG. 14, the second electrode CAT may include a plurality of conductive layers CEE1 and CEE2. For example, the second electrode CAT may include a first conductive layer CEE1 and a second conductive layer CEE2. The second conductive layer CEE2 may be on the first conductive layer CEE1. The first conductive layer CEE1 and the second conductive layer CEE2 may be in contact (or direct contact) with each other.

The first conductive layer CEE1 of the second electrode CAT may include, for example, ytterbium (Yb).

The second conductive layer CEE2 of the second electrode CAT may include, for example, silver (Ag) and/or magnesium (Mg).

According to one or more embodiments, the first conductive layer CEE1 of the second electrode CAT may be in the display area DAA, and the second conductive layer CEE2 of the second electrode CAT may be in the display area DAA and the non-display area NDA. For example, the second electrode CAT may include the first conductive layer CEE1 and the second conductive layer CEE2 in the display area DAA, and may include the second conductive layer CEE2 in the non-display area NDA. For example, the second electrode CAT may include the second conductive layer CEE2 in the cathode contact area B6 of the non-display area NDA and not include the first conductive layer CEE1. In the cathode contact area B6, the second conductive layer CEE2 of the second electrode CAT may be connected to the cathode pad CPD. For example, in cathode contact area B6, the second conductive layer CEE2 of the second electrode CAT and the cathode pad CPD may be in contact (or direct contact) with each other. In one or more embodiments, in the display area DAA, the first conductive layer CEE1 of the second electrode CAT may be connected to the light emitting stack IL of the first conductive layer CEE1. For example, in the display area DAA, the first conductive layer CEE1 of the second electrode CAT may be in contact (or direct contact) with the light emitting stack IL.

Ytterbium (Yb) has the property of being easily oxidized if (e.g., when) exposed to moisture, and thus, the first conductive layer CEE1 containing ytterbium (Yb) may be easily oxidized. As described in one or more embodiments, the second electrode CAT may selectively include only the second conductive layer CEE2 in the cathode contact area B6, thereby reducing the contact resistance (or reducing a degree or occurrence of the contact resistance) between the second electrode CAT and the cathode pad CPD.

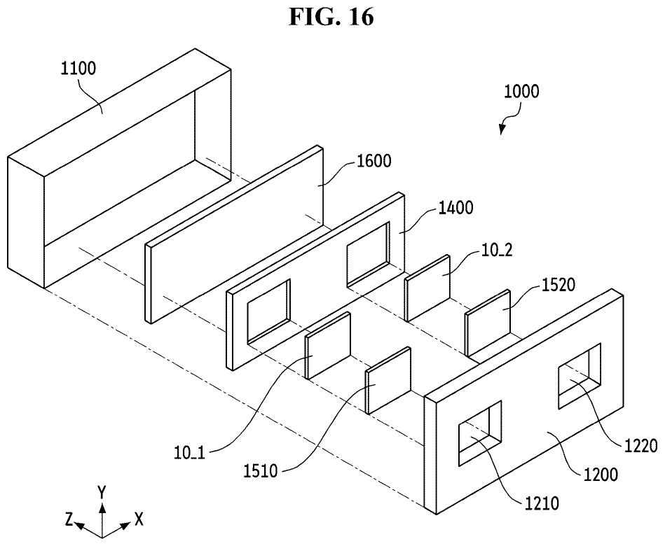

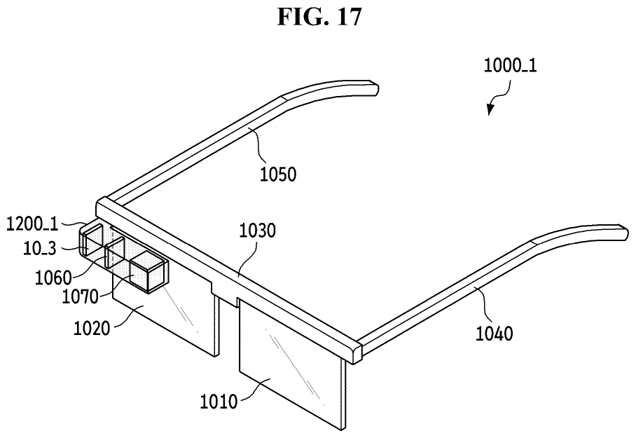

FIG. 15 is a perspective view illustrating a head mounted display according to one or more embodiments. FIG. 16 is an exploded perspective view illustrating an example of the head mounted display of FIG. 15.

Referring to FIGS. 15 and 16, a head mounted display 1000 according to one or more embodiments may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may be to provide an image to the user's left eye, and the second display device 10_2 may be to provide an image to the user's right eye. Because each of the first display device 10_1 and the second display device 10_2 may be substantially the same as the display device 10 as described in conjunction with FIGS. 1 and 2, a description of the first display device 10_1 and the second display device 10_2 may not be provided.

The first optical member 1510 may be between the first display device 10_1 and the first eyepiece 1210. The second optical member 1520 may be between the second display device 10_2 and the second eyepiece 1220. Each of the first optical member 1510 and the second optical member 1520 may include at least one convex lens.

The middle frame 1400 may be between the first display device 10_1 and the control circuit board 1600 and between the second display device 10_2 and the control circuit board 1600. The middle frame 1400 may act or serve to support and fix the first display device 10_1, the second display device 10_2, and the control circuit board 1600.

The control circuit board 1600 may be between the middle frame 1400 and the display device housing 1100. The control circuit board 1600 may be connected to the first display device 10_1 and the second display device 10_2 through the connector. The control circuit board 1600 may be to convert an image source inputted from the outside into the digital video data DATA and transmit the digital video data DATA to the first display device 10_1 and the second display device 10_2 through the connector.

The control circuit board 1600 may be to transmit the digital video data DATA that corresponds to a left-eye image improved or optimized for the user's left eye to the first display device 10_1, and may be to transmit the digital video data DATA that corresponds to a right-eye image improved or optimized for the user's right eye to the second display device 10_2. In one or more embodiments, the control circuit board 1600 may be to transmit substantially the same digital video data DATA to the first display device 10_1 and the second display device 10_2.

The display device housing 1100 may act or serve to accommodate the first display device 10_1, the second display device 10_2, the middle frame 1400, the first optical member 1510, the second optical member 1520, and the control circuit board 1600. The housing cover 1200 may be to cover one open surface of the display device housing 1100. The housing cover 1200 may include the first eyepiece 1210 at which the user's left eye is arranged or provided and the second eyepiece 1220 at which the user's right eye is arranged or provided. FIGS. 15 and 16 illustrate that the first eyepiece 1210 and the second eyepiece 1220 may be arranged or provided separately, but embodiments of the present disclosure are not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

The head mounted band 1300 may act or serve to secure or provide the display device housing 1100 to the user's head such that the first eyepiece 1210 and the second eyepiece 1220 of the housing cover 1200 remain on the user's left eye and right eye, respectively. If (e.g., when) the display device housing 1200 is implemented or utilized to be lightweight and compact, the head mounted display 1000 may be provided with, as shown in FIG. 10, an eyeglass frame instead of the head mounted band 1300.

In one or more embodiments, the head mounted display 1000 may further include a battery to supply power, an external memory slot to accommodate an external memory, and an external connection port and a wireless communication module to receive an image source. The external connection port may be a universe serial bus (USB) terminal, a display port, and/or a high-definition multimedia interface (HDMI) terminal, and the wireless communication module may be a 5G communication module, a 4G communication module, a Wi-Fi module, and/or a Bluetooth module.

FIG. 17 is a perspective view illustrating a head mounted display according to one or more embodiments.

Referring to FIG. 17, a head mounted display 1000_1 according to one or more embodiments may be an eyeglasses-type (kind) display device in which a display device housing 1200_1 is implemented or utilized in a lightweight and compact manner. The head mounted display 1000_1 according to one or more embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060 and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 17 illustrates that the display device housing 1200_1 may be at the right end of the support frame 1030, but embodiments of the present disclosure are not limited thereto. For example, the display device housing 1200_1 may be at the left end of the support frame 1030, and, in one or more embodiments, the image of the display device 10_3 may be provided to the user's left eye. In one or more embodiments, the display device housing 1200_1 may be at both (e.g., simultaneously) the left end and right end of the support frame 1030, and, in one or more embodiments, the user may view the image displayed on the display device 10_3 through both (e.g., simultaneously) the left eye and right eye.

The display device according to one or more embodiments may be applied to one or more suitable electronic devices. The electronic device according to one or more embodiments may include the display device as described in one or more embodiments and may further include modules and/or devices having additional functions in addition to the display device.

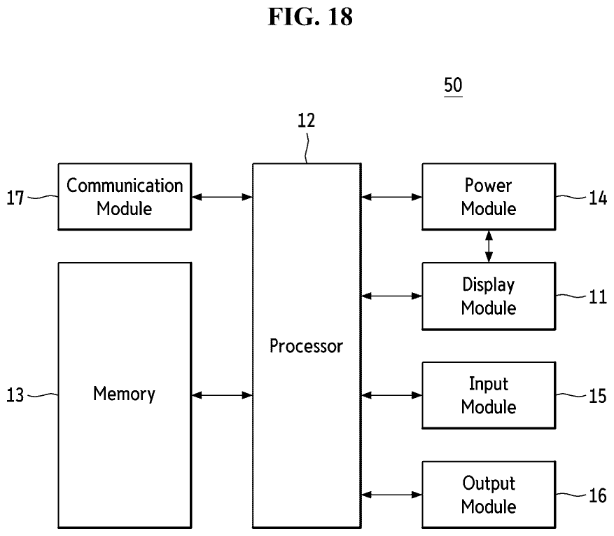

FIG. 18 is a block diagram of an electronic device according to one or more embodiments. Referring to FIG. 18, the electronic device 50 according to one or more embodiments may include a display module (11, e.g., a display device), a processor 12, a memory 13, and a power module 14. The electronic device 50 may further include an input module 14, a non-image output module 15 and/or a communication module 16.

The electronic device 50 may be to output one or more suitable information in the form of images through the display module 11. If (e.g., when) the processor 12 executes an application stored in the memory 13, image information provided by the application may be provided to the user through the display module 11. The power module 14 may include a power supply module, such as a power adapter or a battery device, and a power conversion module that converts the power supplied by the power supply module to generate power desired or required for the operation of the electronic device 50. The input module 14 may be to provide input information to the processor 12 and/or the display module 11. The non-image output module 15 may be to receive information other than images transmitted from the processor 12, such as sound, haptics, and light, and provide the information to the user. The communication module 16 may be a module that is responsible for transmitting and receiving information between the electronic device 50 and an external device, and may include a receiving unit and a transmitting unit.

At least one of the components of the electronic device 50 as described in one or more embodiments may be included in the display device as described in one or more embodiments. In one or more embodiments, one or more of the individual modules functionally included in one module may be included in the display device, and others may be provided separately from the display device. For example, the display device may include a display module 1100, and the processor 12, memory 13, and power module 14 may be provided in the form of other devices within the electronic device 11 other than the display device.

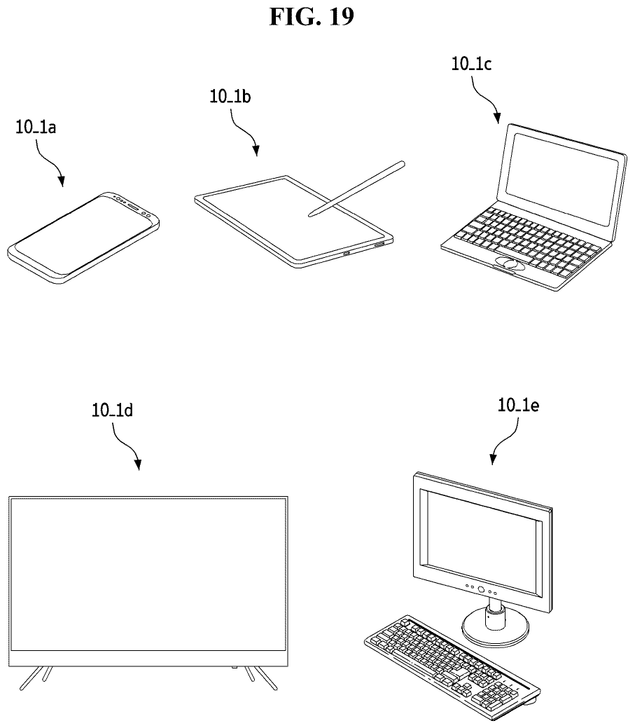

FIGS. 19, 20, and 21 are schematic diagrams of electronic devices according to one or more suitable embodiments. FIGS. 19 to 21 illustrate examples of one or more suitable electronic devices to which the display device according to one or more embodiments is applied.

FIG. 19 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module, such as a touch sensor and/or a communication module. The smartphone 10_1a may process information received through the communication module and/or other input modules and display the information through the display module of the display device.

In the case of tablet PCs 10_1b, laptops 10_1c, TVs 10_1d, and desk monitors 10_1e, they may also include display modules and input modules similar to smartphones 10_1, and may additionally include communication modules in one or more embodiments.

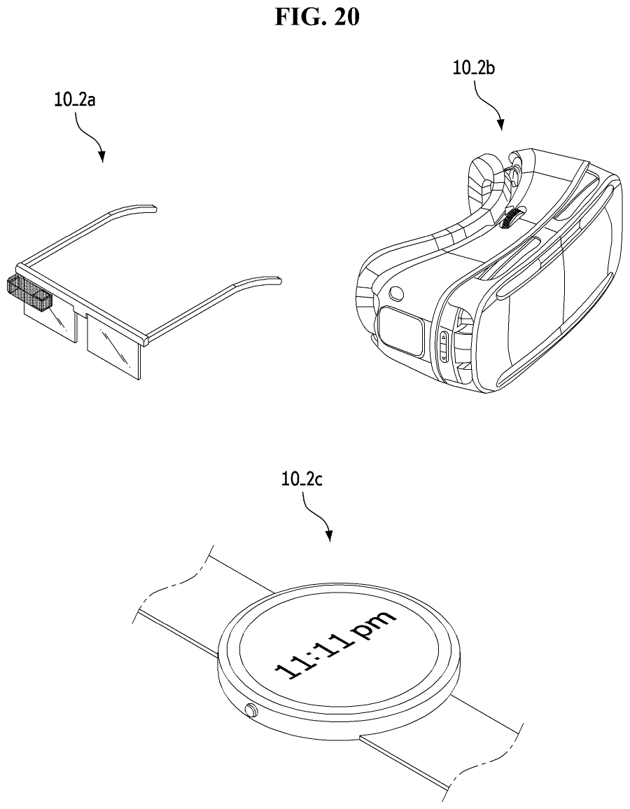

FIG. 20 illustrates an example of an electronic device including a display module being applied to a wearable electronic device. The wearable electronic device may be smart glasses 10_2a, a head-mounted display 10_2b, a smart watch 10_2c, and/or the like.

The smart glasses 10_2a and the head-mounted display 10_2b may include a display module that is to emit a display image and a reflector that is to reflect the emitted display screen and provide it to the user's eyes, thereby providing a virtual reality or augmented reality screen to the user.

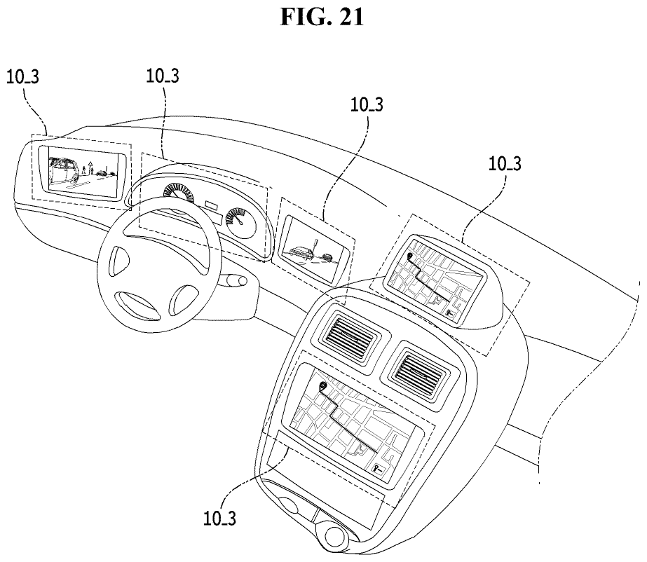

The smart watch 10_2c may include a biometric sensor as an input device and may provide biometric information recognized by the biometric sensor to the user through the display module. FIG. 21 illustrates a case where an electronic device including a display module is applied to a vehicle. For example, the electronic device 10_3 may be applied to a dashboard, center fascia, and/or the like of a vehicle and/or may be applied to a Center Information Display (CID) placed on a dashboard of a vehicle and/or a room mirror display that replaces a side mirror.

A display device/apparatus, an electronic device/apparatus, a device/apparatus for manufacturing substantially the same and/or any other relevant devices, apparatus, or components according to embodiments of the present disclosure described herein may be implemented by utilizing any suitable hardware, firmware (e.g., an application-specific integrated circuit), software, or a combination of software, firmware, and hardware. For example, the one or more suitable components of the device may be formed or provided on one integrated circuit (IC) chip or on separate IC chips. Further, the one or more suitable components of the device may be implemented on a flexible printed circuit film, a tape carrier package (TCP), a printed circuit board (PCB), or formed on one substrate. Further, the one or more suitable components of the device may be a process or thread, running on one or more processors, in one or more computing devices, executing computer program instructions and interacting with other system components to perform the one or more functionalities described herein. The computer program instructions may be stored in a memory which may be implemented in a computing device using a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

It will be understood by one of ordinary skill in the art to which the present disclosure belongs that the present disclosure may be implemented in one or more suitable forms without changing the spirit and scope of the present disclosure.

Therefore, it will be understood that one or more embodiments described above are illustrative rather than being restrictive in all aspects. It will be understood that the scope of the present disclosure are defined by the scope of the appended claims and equivalents thereof rather than the detailed description described above and all modifications and alterations derived from the appended claims and their equivalents fall within the scope of the present disclosure.

What is claimed is:

1. A display device, comprising:
a substrate;
a first electrode on the substrate;
a pixel defining layer on the first electrode;
a light emitting stack on the first electrode and the pixel defining layer;
a second electrode on the light emitting stack; and
a cathode pad connected to the second electrode through a contact area defined by the pixel defining layer in a cathode contact area of the substrate,
wherein the cathode pad is continuous in the contact area without disconnection.

2. The display device as claimed in claim 1,
wherein the cathode pad does not have a step in the contact area.

3. The display device as claimed in claim 1,
wherein the cathode pad has a flat shape in the contact area.

4. The display device as claimed in claim 1,
wherein, in plan view, an area of the cathode pad is substantially the same as an area of the contact area.

5. The display device as claimed in claim 1,
wherein, in plan view, the cathode pad occupies all of the contact area.

6. The display device as claimed in claim 1,
wherein the second electrode comprises a plurality of conductive layers.

7. The display device as claimed in claim 6,
wherein the second electrode comprises:
a first conductive layer comprising ytterbium; and
a second conductive layer comprising silver and magnesium.

8. The display device as claimed in claim 7,
wherein, in a display area of the substrate, the first conductive layer and the second conductive layer of the second electrode are provided, and
wherein, in the cathode contact area of the substrate, the second conductive layer of the second electrode is provided.

9. The display device as claimed in claim 8,
wherein the second conductive layer of the second electrode is connected to the cathode pad through the contact area.

10. The display device as claimed in claim 1,
wherein the cathode pad is connected to a driving voltage line.

11. An optical device, comprising:
a display device; and
an optical path conversion member on the display device,
wherein the display device comprises:
a substrate;
a first electrode on the substrate;
a pixel defining layer on the first electrode;
a light emitting stack on the first electrode and the pixel defining layer;
a second electrode on the light emitting stack; and
a cathode pad connected to the second electrode through a contact area defined by the pixel defining layer in a cathode contact area of the substrate, and
wherein the cathode pad is continuous in the contact area without disconnection.

12. The optical device as claimed in claim 11,
wherein the cathode pad does not have a step in the contact area.

13. The optical device as claimed in claim 11,
wherein the cathode pad has a flat shape in the contact area.

14. The optical device as claimed in claim 11,
wherein, in plan view, an area of the cathode pad is substantially the same as an area of the contact area.

15. The optical device as claimed in claim 11,
wherein, in plan view, the cathode pad occupies all of the contact area.

16. The optical device as claimed in claim 11,
wherein the second electrode comprises a plurality of conductive layers.

17. The optical device as claimed in claim 16,
wherein the second electrode comprises:
a first conductive layer comprising ytterbium; and
a second conductive layer comprising silver and magnesium.

18. The optical device as claimed in claim 17,
wherein, in a display area of the substrate, the first conductive layer and the second conductive layer of the second electrode are provided, and
wherein, in the cathode contact area of the substrate, the second conductive layer of the second electrode is provided.

19. The optical device as claimed in claim 18,
wherein the second conductive layer of the second electrode is connected to the cathode pad through the contact area.

20. An electronic device, comprising:
a display device comprising:
a screen;
a substrate;
a first electrode on the substrate;
a pixel defining layer on the first electrode;
a light emitting stack on the first electrode and the pixel defining layer;
a second electrode on the light emitting stack; and
a cathode pad connected to the second electrode through a contact area defined by the pixel defining layer in a cathode contact area of the substrate,
wherein the cathode pad is continuous in the contact area without disconnection.
